(19) United States
(12) Patent Application Publication
(10) Pub. No.: US 2026/0205337 A1
(43) Pub. Date: Jul. 16, 2026

(54) ENERGY BASED SPLITTING AND COMBINING FOR PROBABILISTIC AMPLITUDE SHAPING BASED COMMUNICATION

(71) Applicant: QUALCOMM Incorporated, San Diego, CA (US)

(72) Inventors: Wei LIU, Beijing (CN); Thomas Joseph RICHARDSON, South Orange, NJ (US); Liangming WU, Beijing (CN); Changlong XU, Beijing (CN); Ori SHENTAL, Marlboro, NJ (US); Hao XU, Beijing (CN)

(21) Appl. No.: 19/138,503

(22) PCT Filed: Jan. 31, 2023
(86) PCT No.: PCT/CN2023/073921

§ 371 Date: Jun. 12, 2025

(51) Int. Cl. H04L 27/26; H03M 7/26; H04L 1/00

(52) U.S. Cl. CPC H04L 27/2607; H03M 7/26; H04L 1/0042

(57) ABSTRACT

Various aspects of the present disclosure generally relate to wireless communication. In some aspects, a transmitter device may receive a plurality of information bits, the plurality of information bits being associated with a set of integers. The transmitter device may perform a first encoding operation on a first integer, of the set of integers, the first encoding operation being associated with an alphabet, a sequence length, and an energy threshold. The transmitter device may perform a second encoding operation on a second integer to generate a prefix subsequence. The transmitter device may perform a third encoding operation on a third integer to generate a postfix subsequence. The transmitter device may generate a symbol sequence based at least in part on the prefix subsequence and the postfix subsequence. The transmitter device may transmit the symbol sequence to convey the plurality of information bits. Numerous other aspects are described.

### FIELD OF THE DISCLOSURE

Aspects of the present disclosure generally relate to wireless communication and to techniques and apparatuses for energy based splitting and combining for probabilistic amplitude shaping based communication.

### BACKGROUND

Wireless communication systems are widely deployed to provide various telecommunication services such as telephony, video, data, messaging, and broadcasts. Typical wireless communication systems may employ multiple-access technologies capable of supporting communication with multiple users by sharing available system resources (e.g., bandwidth, transmit power, or the like). Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, time division synchronous code division multiple access (TD-SCDMA) systems, and Long Term Evolution (LTE). LTE/LTE-Advanced is a set of enhancements to the Universal Mobile Telecommunications System (UMTS) mobile standard promulgated by the Third Generation Partnership Project (3GPP).

A wireless network may include one or more network nodes that support communication for wireless communication devices, such as a user equipment (UE) or multiple UEs. A UE may communicate with a network node via downlink communications and uplink communications. “Downlink” (or “DL”) refers to a communication link from the network node to the UE, and “uplink” (or “UL”) refers to a communication link from the UE to the network node. Some wireless networks may support device-to-device communication, such as via a local link (e.g., a sidelink (SL), a wireless local area network (WLAN) link, and/or a wireless personal area network (WPAN) link, among other examples).

The above multiple access technologies have been adopted in various telecommunication standards to provide a common protocol that enables different UEs to communicate on a municipal, national, regional, and/or global level. New Radio (NR), which may be referred to as 5G, is a set of enhancements to the LTE mobile standard promulgated by the 3GPP. NR is designed to better support mobile broadband internet access by improving spectral efficiency, lowering costs, improving services, making use of new spectrum, and better integrating with other open standards using orthogonal frequency division multiplexing (OFDM) with a cyclic prefix (CP) (CP-OFDM) on the downlink, using CP-OFDM and/or single-carrier frequency division multiplexing (SC-FDM) (also known as discrete Fourier transform spread OFDM (DFT-s-OFDM)) on the uplink, as well as supporting beamforming, multiple-input multiple-output (MIMO) antenna technology, and carrier aggregation. As the demand for mobile broadband access continues to increase, further improvements in LTE, NR, and other radio access technologies remain useful.

### SUMMARY

Some aspects described herein relate to a method of wireless communication performed by a transmitter device. The method may include receiving a plurality of information bits, the plurality of information bits being associated with a set of integers. The method may include performing a first encoding operation on a first integer, of the set of integers, the first encoding operation being associated with an alphabet, a sequence length, and an energy threshold, and the first encoding operation including determining a prefix subsequence energy based at least in part on a prefix subsequence length, the sequence length, the energy threshold, and the first integer, generating a shifted first integer based at least in part on the prefix subsequence energy and the first integer, and determining a second integer and a third integer based at least in part on the shifted first integer and the prefix subsequence energy. The method may include performing a second encoding operation on the second integer to generate a prefix subsequence. The method may include performing a third encoding operation on the third integer to generate a postfix subsequence. The method may include generating a symbol sequence based at least in part on the prefix subsequence and the postfix subsequence. The method may include transmitting the symbol sequence to convey the plurality of information bits.

Some aspects described herein relate to a method of wireless communication performed by a receiver device. The method may include receiving a symbol sequence that conveys a plurality of information bits. The method may include determining a prefix subsequence and a postfix subsequence based at least in part on the symbol sequence. The method may include performing a first decoding operation on the prefix subsequence to determine a first integer. The method may include performing a second decoding operation on the postfix subsequence to determine a second integer. The method may include performing a third decoding operation on the first integer and the second integer to determine a third integer, the third decoding operation being associated with an alphabet, a sequence length, and an energy threshold, and the third decoding operation including determining a shifted third integer based at least in part on the second integer and the third integer, and determining the third integer based at least in part on the shifted third integer, a prefix subsequence energy, a prefix subsequence length, the sequence length, and the energy threshold. The method may include recovering the plurality of information bits associated with a set of integers, the set of integers including the first integer, the second integer, and the third integer.

Some aspects described herein relate to a transmitter device for wireless communication. The transmitter device may include a memory and one or more processors coupled to the memory. The one or more processors may be configured to receive a plurality of information bits, the plurality of information bits being associated with a set of integers. The one or more processors may be configured to perform a first encoding operation on a first integer, of the set of integers, the first encoding operation being associated with an alphabet, a sequence length, and an energy threshold, and the first encoding operation including the one or more processors being configured to determine a prefix subsequence energy based at least in part on a prefix subsequence length, the sequence length, the energy threshold, and the first integer, generate a shifted first integer based at least in part on the prefix subsequence energy and the first integer, and determine a second integer and a third integer based at least in part on the shifted first integer and the prefix subsequence energy. The one or more processors may be configured to perform a second encoding operation on the second integer to generate a prefix subsequence. The one or more processors may be configured to perform a third encoding operation on the third integer to generate a postfix subsequence. The one or more processors may be configured to generate a symbol sequence based at least in part on the prefix subsequence and the postfix subsequence. The one or more processors may be configured to transmit the symbol sequence to convey the plurality of information bits.

Some aspects described herein relate to a receiver device for wireless communication. The receiver device may include a memory and one or more processors coupled to the memory. The one or more processors may be configured to receive a symbol sequence that conveys a plurality of information bits. The one or more processors may be configured to determine a prefix subsequence and a postfix subsequence based at least in part on the symbol sequence. The one or more processors may be configured to perform a first decoding operation on the prefix subsequence to determine a first integer. The one or more processors may be configured to perform a second decoding operation on the postfix subsequence to determine a second integer. The one or more processors may be configured to perform a third decoding operation on the first integer and the second integer to determine a third integer, the third decoding operation being associated with an alphabet, a sequence length, and an energy threshold, and the third decoding operation including the one or more processors being configured to determine a shifted third integer based at least in part on the second integer and the third integer, and determine the third integer based at least in part on the shifted third integer, a prefix subsequence energy, a prefix subsequence length, the sequence length, and the energy threshold. The one or more processors may be configured to recover the plurality of information bits associated with a set of integers, the set of integers including the first integer, the second integer, and the third integer.

Some aspects described herein relate to a non-transitory computer-readable medium that stores a set of instructions for wireless communication by a transmitter device. The set of instructions, when executed by one or more processors of the transmitter device, may cause the transmitter device to receive a plurality of information bits, the plurality of information bits being associated with a set of integers. The set of instructions, when executed by one or more processors of the transmitter device, may cause the transmitter device to perform a first encoding operation on a first integer, of the set of integers, the first encoding operation being associated with an alphabet, a sequence length, and an energy threshold, and the first encoding operation including causing the transmitter device to determine a prefix subsequence energy based at least in part on a prefix subsequence length, the sequence length, the energy threshold, and the first integer, generate a shifted first integer based at least in part on the prefix subsequence energy and the first integer, and determine a second integer and a third integer based at least in part on the shifted first integer and the prefix subsequence energy. The set of instructions, when executed by one or more processors of the transmitter device, may cause the transmitter device to perform a second encoding operation on the second integer to generate a prefix subsequence. The set of instructions, when executed by one or more processors of the transmitter device, may cause the transmitter device to perform a third encoding operation on the third integer to generate a postfix subsequence. The set of instructions, when executed by one or more processors of the transmitter device, may cause the transmitter device to generate a symbol sequence based at least in part on the prefix subsequence and the postfix subsequence. The set of instructions, when executed by one or more processors of the transmitter device, may cause the transmitter device to transmit the symbol sequence to convey the plurality of information bits.

Some aspects described herein relate to a non-transitory computer-readable medium that stores a set of instructions for wireless communication by a receiver device. The set of instructions, when executed by one or more processors of the receiver device, may cause the receiver device to receive a symbol sequence that conveys a plurality of information bits. The set of instructions, when executed by one or more processors of the receiver device, may cause the receiver device to determine a prefix subsequence and a postfix subsequence based at least in part on the symbol sequence. The set of instructions, when executed by one or more processors of the receiver device, may cause the receiver device to perform a first decoding operation on the prefix subsequence to determine a first integer. The set of instructions, when executed by one or more processors of the receiver device, may cause the receiver device to perform a second decoding operation on the postfix subsequence to determine a second integer. The set of instructions, when executed by one or more processors of the receiver device, may cause the receiver device to perform a third decoding operation on the first integer and the second integer to determine a third integer, the third decoding operation being associated with an alphabet, a sequence length, and an energy threshold, and the third encoding operation including causing the receiver device to determine a shifted third integer based at least in part on the second integer and the third integer, and determine the third integer based at least in part on the shifted third integer, a prefix subsequence energy, a prefix subsequence length, the sequence length, and the energy threshold. The set of instructions, when executed by one or more processors of the receiver device, may cause the receiver device to recover the plurality of information bits associated with a set of integers, the set of integers including the first integer, the second integer, and the third integer.

Some aspects described herein relate to an apparatus for wireless communication. The apparatus may include means for receiving a plurality of information bits, the plurality of information bits being associated with a set of integers. The apparatus may include means for performing a first encoding operation on a first integer, of the set of integers, the first encoding operation being associated with an alphabet, a sequence length, and an energy threshold, and the means for performing the first encoding operation, including means for determining a prefix subsequence energy based at least in part on a prefix subsequence length, the sequence length, the energy threshold, and the first integer, means for generating a shifted first integer based at least in part on the prefix subsequence energy and the first integer, and means for determining a second integer and a third integer based at least in part on the shifted first integer and the prefix subsequence energy. The apparatus may include means for performing a second encoding operation on the second integer to generate a prefix subsequence. The apparatus may include means for performing a third encoding operation on the third integer to generate a postfix subsequence. The apparatus may include means for generating a symbol sequence based at least in part on the prefix subsequence and the postfix subsequence. The apparatus may include means for transmitting the symbol sequence to convey the plurality of information bits.

Some aspects described herein relate to an apparatus for wireless communication. The apparatus may include means for receiving a symbol sequence that conveys a plurality of information bits. The apparatus may include means for determining a prefix subsequence and a postfix subsequence based at least in part on the symbol sequence. The apparatus may include means for performing a first decoding operation on the prefix subsequence to determine a first integer. The apparatus may include means for performing a second decoding operation on the postfix subsequence to determine a second integer. The apparatus may include means for performing a third decoding operation on the first integer and the second integer to determine a third integer, the third decoding operation being associated with an alphabet, a sequence length, and an energy threshold, and the means for performing the third decoding operation, including means for determining a shifted third integer based at least in part on the second integer and the third integer, and means for determining the third integer based at least in part on the shifted third integer, a prefix subsequence energy, a prefix subsequence length, the sequence length, and the energy threshold. The apparatus may include means for recovering the plurality of information bits associated with a set of integers, the set of integers including the first integer, the second integer, and the third integer.

Aspects generally include a method, apparatus, system, computer program product, non-transitory computer-readable medium, user equipment, base station, network entity, network node, wireless communication device, and/or processing system as substantially described herein with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages, will be better understood from the following description when considered in connection with the accompanying figures. Each of the figures is provided for the purposes of illustration and description, and not as a definition of the limits of the claims.

While aspects are described in the present disclosure by illustration to some examples, those skilled in the art will understand that such aspects may be implemented in many different arrangements and scenarios. Techniques described herein may be implemented using different platform types, devices, systems, shapes, sizes, and/or packaging arrangements. For example, some aspects may be implemented via integrated chip embodiments or other non-module-component based devices (e.g., end-user devices, vehicles, communication devices, computing devices, industrial equipment, retail/purchasing devices, medical devices, and/or artificial intelligence devices). Aspects may be implemented in chip-level components, modular components, non-modular components, non-chip-level components, device-level components, and/or system-level components. Devices incorporating described aspects and features may include additional components and features for implementation and practice of claimed and described aspects. For example, transmission and reception of wireless signals may include one or more components for analog and digital purposes (e.g., hardware components including antennas, radio frequency (RF) chains, power amplifiers, modulators, buffers, processors, interleavers, adders, and/or summers). It is intended that aspects described herein may be practiced in a wide variety of devices, components, systems, distributed arrangements, and/or end-user devices of varying size, shape, and constitution.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating an example of a wireless network, in accordance with the present disclosure.

FIG. 2 is a diagram illustrating an example of a network node in communication with a user equipment (UE) in a wireless network, in accordance with the present disclosure.

FIG. 3 is a diagram illustrating an example disaggregated base station architecture, in accordance with the present disclosure.

FIG. 4 is a diagram illustrating an example of a transmit (Tx) chain and a receive (Rx) chain of a UE in accordance with the present disclosure.

FIG. 5 is a diagram illustrating an example transmit chain for probabilistic amplitude shaping in accordance with the present disclosure.

FIG. 6 is a diagram illustrating an example transmit chain for probabilistic amplitude shaping in accordance with the present disclosure.

FIG. 7 is a diagram illustrating an example transmit chain for energy-based probabilistic amplitude shaping in accordance with the present disclosure.

FIGS. 8A and 8B are diagrams of an example associated with energy based splitting and combining for probabilistic amplitude shaping based communication, in accordance with the present disclosure.

FIG. 9 is a diagram illustrating an example process performed, for example, by a transmitter device, in accordance with the present disclosure.

FIG. 10 is a diagram illustrating an example process performed, for example, by a receiver device, in accordance with the present disclosure.

FIG. 11 is a diagram of an example apparatus for wireless communication, in accordance with the present disclosure.

FIG. 12 is a diagram of an example apparatus for wireless communication, in accordance with the present disclosure.

### DETAILED DESCRIPTION

A transmitter device may perform energy-based shaping to encode information bit sequences to one a symbol sequence. Two example techniques for the encoding include a direct energy-based arithmetic coding (AC) method and a two-stage peeling method. However, these encoding methods are implemented as serial processes. For example, the underlying direct energy-based AC method is a serially implemented method, which may result in excess latency to encode and transmit latency-sensitive communications. Some aspects described herein provide for low-latency energy-based probabilistic amplitude shaping. For example, some aspects described herein enable dividing of an encoding problem into a set of sub-encoding problems for parallel processing, which reduces a latency associated with generating a signal for transmission. Similarly, some aspects described herein may be applied to enable parallel decoding techniques, thereby reducing a latency associated with decoding of transmissions.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

Several aspects of telecommunication systems will now be presented with reference to various apparatuses and techniques. These apparatuses and techniques will be described in the following detailed description and illustrated in the accompanying drawings by various blocks, modules, components, circuits, steps, processes, algorithms, or the like (collectively referred to as “elements”). These elements may be implemented using hardware, software, or combinations thereof. Whether such elements are implemented as hardware or software depends upon the particular application and design constraints imposed on the overall system.

While aspects may be described herein using terminology commonly associated with a 5G or New Radio (NR) radio access technology (RAT), aspects of the present disclosure can be applied to other RATs, such as a 3G RAT, a 4G RAT, and/or a RAT subsequent to 5G (e.g., 6G).

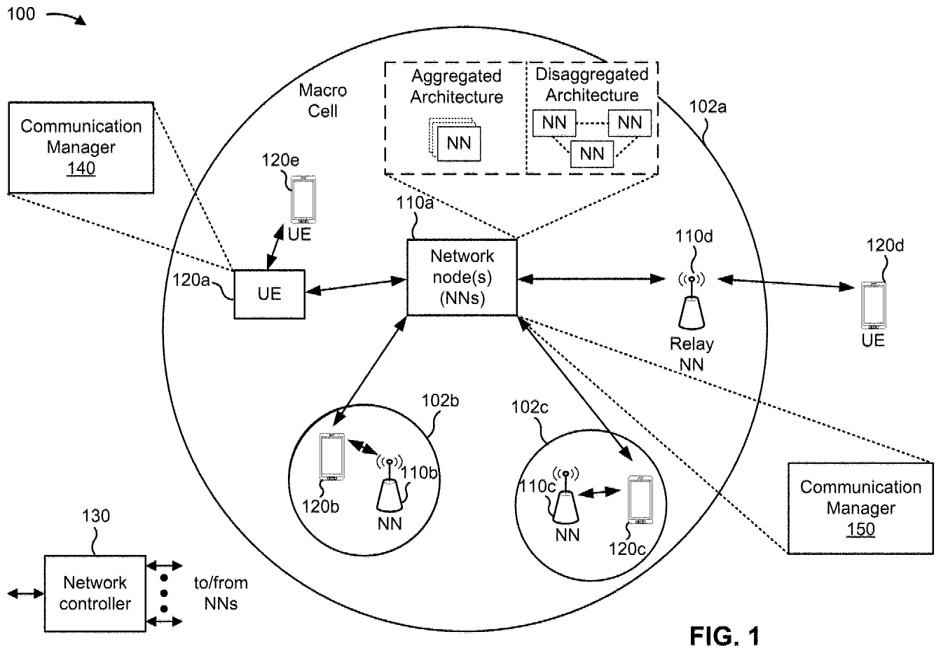

FIG. 1 is a diagram illustrating an example of a wireless network 100, in accordance with the present disclosure. The wireless network 100 may be or may include elements of a 5G (e.g., NR) network and/or a 4G (e.g., Long Term Evolution (LTE)) network, among other examples. The wireless network 100 may include one or more network nodes 110 (shown as a network node 110a, a network node 110b, a network node 110c, and a network node 110d), a user equipment (UE) 120 or multiple UEs 120 (shown as a UE 120a, a UE 120b, a UE 120c, a UE 120d, and a UE 120e), and/or other entities. A network node 110 is a network node that communicates with UEs 120. As shown, a network node 110 may include one or more network nodes. For example, a network node 110 may be an aggregated network node, meaning that the aggregated network node is configured to utilize a radio protocol stack that is physically or logically integrated within a single radio access network (RAN) node (e.g., within a single device or unit). As another example, a network node 110 may be a disaggregated network node (sometimes referred to as a disaggregated base station), meaning that the network node 110 is configured to utilize a protocol stack that is physically or logically distributed among two or more nodes (such as one or more central units (CUs), one or more distributed units (DUs), or one or more radio units (RUs)).

In some examples, a network node 110 is or includes a network node that communicates with UEs 120 via a radio access link, such as an RU. In some examples, a network node 110 is or includes a network node that communicates with other network nodes 110 via a fronthaul link or a midhaul link, such as a DU. In some examples, a network node 110 is or includes a network node that communicates with other network nodes 110 via a midhaul link or a core network via a backhaul link, such as a CU. In some examples, a network node 110 (such as an aggregated network node 110 or a disaggregated network node 110) may include multiple network nodes, such as one or more RUs, one or more CUs, and/or one or more DUs. A network node 110 may include, for example, an NR base station, an LTE base station, a Node B, an eNB (e.g., in 4G), a gNB (e.g., in 5G), an access point, a transmission reception point (TRP), a DU, an RU, a CU, a mobility element of a network, a core network node, a network element, a network equipment, a RAN node, or a combination thereof. In some examples, the network nodes 110 may be interconnected to one another or to one or more other network nodes 110 in the wireless network 100 through various types of fronthaul, midhaul, and/or backhaul interfaces, such as a direct physical connection, an air interface, or a virtual network, using any suitable transport network.

In some examples, a network node 110 may provide communication coverage for a particular geographic area. In the Third Generation Partnership Project (3GPP), the term “cell” can refer to a coverage area of a network node 110 and/or a network node subsystem serving this coverage area, depending on the context in which the term is used. A network node 110 may provide communication coverage for a macro cell, a pico cell, a femto cell, and/or another type of cell. A macro cell may cover a relatively large geographic area (e.g., several kilometers in radius) and may allow unrestricted access by UEs 120 with service subscriptions. A pico cell may cover a relatively small geographic area and may allow unrestricted access by UEs 120 with service subscriptions. A femto cell may cover a relatively small geographic area (e.g., a home) and may allow restricted access by UEs 120 having association with the femto cell (e.g., UEs 120 in a closed subscriber group (CSG)). A network node 110 for a macro cell may be referred to as a macro network node. A network node 110 for a pico cell may be referred to as a pico network node. A network node 110 for a femto cell may be referred to as a femto network node or an in-home network node. In the example shown in FIG. 1, the network node 110a may be a macro network node for a macro cell 102a, the network node 110b may be a pico network node for a pico cell 102b, and the network node 110c may be a femto network node for a femto cell 102c. A network node may support one or multiple (e.g., three) cells. In some examples, a cell may not necessarily be stationary, and the geographic area of the cell may move according to the location of a network node 110 that is mobile (e.g., a mobile network node).

In some aspects, the terms “base station” or “network node” may refer to an aggregated base station, a disaggregated base station, an integrated access and backhaul (IAB) node, a relay node, or one or more components thereof. For example, in some aspects, “base station” or “network node” may refer to a CU, a DU, an RU, a Near-Real Time (Near-RT) RAN Intelligent Controller (RIC), or a Non-Real Time (Non-RT) RIC, or a combination thereof. In some aspects, the terms “base station” or “network node” may refer to one device configured to perform one or more functions, such as those described herein in connection with the network node 110. In some aspects, the terms “base station” or “network node” may refer to a plurality of devices configured to perform the one or more functions. For example, in some distributed systems, each of a quantity of different devices (which may be located in the same geographic location or in different geographic locations) may be configured to perform at least a portion of a function, or to duplicate performance of at least a portion of the function, and the terms “base station” or “network node” may refer to any one or more of those different devices. In some aspects, the terms “base station” or “network node” may refer to one or more virtual base stations or one or more virtual base station functions. For example, in some aspects, two or more base station functions may be instantiated on a single device. In some aspects, the terms “base station” or “network node” may refer to one of the base station functions and not another. In this way, a single device may include more than one base station.

The wireless network 100 may include one or more relay stations. A relay station is a network node that can receive a transmission of data from an upstream node (e.g., a network node 110 or a UE 120) and send a transmission of the data to a downstream node (e.g., a UE 120 or a network node 110). A relay station may be a UE 120 that can relay transmissions for other UEs 120. In the example shown in FIG. 1, the network node 110d (e.g., a relay network node) may communicate with the network node 110a (e.g., a macro network node) and the UE 120d in order to facilitate communication between the network node 110a and the UE 120d. A network node 110 that relays communications may be referred to as a relay station, a relay base station, a relay network node, a relay node, a relay, or the like.

The wireless network 100 may be a heterogeneous network that includes network nodes 110 of different types, such as macro network nodes, pico network nodes, femto network nodes, relay network nodes, or the like. These different types of network nodes 110 may have different transmit power levels, different coverage areas, and/or different impacts on interference in the wireless network 100. For example, macro network nodes may have a high transmit power level (e.g., 5 to 40 watts) whereas pico network nodes, femto network nodes, and relay network nodes may have lower transmit power levels (e.g., 0.1 to 2 watts).

A network controller 130 may couple to or communicate with a set of network nodes 110 and may provide coordination and control for these network nodes 110. The network controller 130 may communicate with the network nodes 110 via a backhaul communication link or a midhaul communication link. The network nodes 110 may communicate with one another directly or indirectly via a wireless or wireline backhaul communication link. In some aspects, the network controller 130 may be a CU or a core network device, or may include a CU or a core network device.

The UEs 120 may be dispersed throughout the wireless network 100, and each UE 120 may be stationary or mobile. A UE 120 may include, for example, an access terminal, a terminal, a mobile station, and/or a subscriber unit. A UE 120 may be a cellular phone (e.g., a smart phone), a personal digital assistant (PDA), a wireless modem, a wireless communication device, a handheld device, a laptop computer, a cordless phone, a wireless local loop (WLL) station, a tablet, a camera, a gaming device, a netbook, a smartbook, an ultrabook, a medical device, a biometric device, a wearable device (e.g., a smart watch, smart clothing, smart glasses, a smart wristband, smart jewelry (e.g., a smart ring or a smart bracelet)), an entertainment device (e.g., a music device, a video device, and/or a satellite radio), a vehicular component or sensor, a smart meter/sensor, industrial manufacturing equipment, a global positioning system device, a UE function of a network node, and/or any other suitable device that is configured to communicate via a wireless or wired medium.

Some UEs 120 may be considered machine-type communication (MTC) or evolved or enhanced machine-type communication (eMTC) UEs. An MTC UE and/or an eMTC UE may include, for example, a robot, a drone, a remote device, a sensor, a meter, a monitor, and/or a location tag, that may communicate with a network node, another device (e.g., a remote device), or some other entity. Some UEs 120 may be considered Internet-of-Things (IoT) devices, and/or may be implemented as NB-IoT (narrowband IoT) devices. Some UEs 120 may be considered a Customer Premises Equipment. A UE 120 may be included inside a housing that houses components of the UE 120, such as processor components and/or memory components. In some examples, the processor components and the memory components may be coupled together. For example, the processor components (e.g., one or more processors) and the memory components (e.g., a memory) may be operatively coupled, communicatively coupled, electronically coupled, and/or electrically coupled.

In general, any number of wireless networks 100 may be deployed in a given geographic area. Each wireless network 100 may support a particular RAT and may operate on one or more frequencies. A RAT may be referred to as a radio technology, an air interface, or the like. A frequency may be referred to as a carrier, a frequency channel, or the like. Each frequency may support a single RAT in a given geographic area in order to avoid interference between wireless networks of different RATs. In some cases, NR or 5G RAT networks may be deployed.

In some examples, two or more UEs 120 (e.g., shown as UE 120a and UE 120e) may communicate directly using one or more sidelink channels (e.g., without using a network node 110 as an intermediary to communicate with one another). For example, the UEs 120 may communicate using peer-to-peer (P2P) communications, device-to-device (D2D) communications, a vehicle-to-everything (V2X) protocol (e.g., which may include a vehicle-to-vehicle (V2V) protocol, a vehicle-to-infrastructure (V2I) protocol, or a vehicle-to-pedestrian (V2P) protocol), and/or a mesh network. In such examples, a UE 120 may perform scheduling operations, resource selection operations, and/or other operations described elsewhere herein as being performed by the network node 110.

Devices of the wireless network 100 may communicate using the electromagnetic spectrum, which may be subdivided by frequency or wavelength into various classes, bands, channels, or the like. For example, devices of the wireless network 100 may communicate using one or more operating bands. In 5G NR, two initial operating bands have been identified as frequency range designations FR1 (410 MHz-7.125 GHZ) and FR2 (24.25 GHz-52.6 GHz). It should be understood that although a portion of FR1 is greater than 6 GHz, FR1 is often referred to (interchangeably) as a “Sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR4a or FR4-1 (52.6 GHz-71 GHz), FR4 (52.6 GHz-114.25 GHZ), and FR5 (114.25 GHZ-300 GHz). Each of these higher frequency bands falls within the EHF band.

With the above examples in mind, unless specifically stated otherwise, it should be understood that the term “sub-6 GHz” or the like, if used herein, may broadly represent frequencies that may be less than 6 GHZ, may be within FR1, or may include mid-band frequencies. Further, unless specifically stated otherwise, it should be understood that the term “millimeter wave” or the like, if used herein, may broadly represent frequencies that may include mid-band frequencies, may be within FR2, FR4, FR4-a or FR4-1, and/or FR5, or may be within the EHF band. It is contemplated that the frequencies included in these operating bands (e.g., FR1, FR2, FR3, FR4, FR4-a, FR4-1, and/or FR5) may be modified, and techniques described herein are applicable to those modified frequency ranges.

In some aspects, a transmitter device (e.g., a UE 120 or a network node 110) may include a communication manager 140/150. As described in more detail elsewhere herein, the communication manager 140/150 may receive a plurality of information bits, the plurality of information bits being associated with a set of integers; perform a first encoding operation on a first integer, of the set of integers, the first encoding operation being associated with an alphabet, a sequence length, and an energy threshold, and the first encoding operation including: determining a prefix subsequence energy based at least in part on a prefix subsequence length, the sequence length, the energy threshold, and the first integer, generating a shifted first integer based at least in part on the prefix subsequence energy and the first integer, and determining a second integer and a third integer based at least in part on the shifted first integer and the prefix subsequence energy; perform a second encoding operation on the second integer to generate a prefix subsequence; perform a third encoding operation on the third integer to generate a postfix subsequence; generate a symbol sequence based at least in part on the prefix subsequence and the postfix subsequence; and transmit the symbol sequence to convey the plurality of information bits. Additionally, or alternatively, the communication manager 140/150 may perform one or more other operations described herein.

In some aspects, the receiver device (e.g., a UE 120 or a network node 110) may include a communication manager 140/150. As described in more detail elsewhere herein, the communication manager 140/150 may receive a symbol sequence that conveys a plurality of information bits; determine a prefix subsequence and a postfix subsequence based at least in part on the symbol sequence; perform a first decoding operation on the prefix subsequence to determine a first integer; perform a second decoding operation on the postfix subsequence to determine a second integer; perform a third decoding operation on the first integer and the second integer to determine a third integer, the third decoding operation being associated with an alphabet, a sequence length, and an energy threshold, and the third decoding operation including: determining a shifted third integer based at least in part on the second integer and the third integer, and determining the third integer based at least in part on the shifted third integer, a prefix subsequence energy, a prefix subsequence length, the sequence length, and the energy threshold; and recover the plurality of information bits associated with a set of integers, the set of integers including the first integer, the second integer, and the third integer. Additionally, or alternatively, the communication manager 140/150 may perform one or more other operations described herein.

As indicated above, FIG. 1 is provided as an example. Other examples may differ from what is described with regard to FIG. 1.

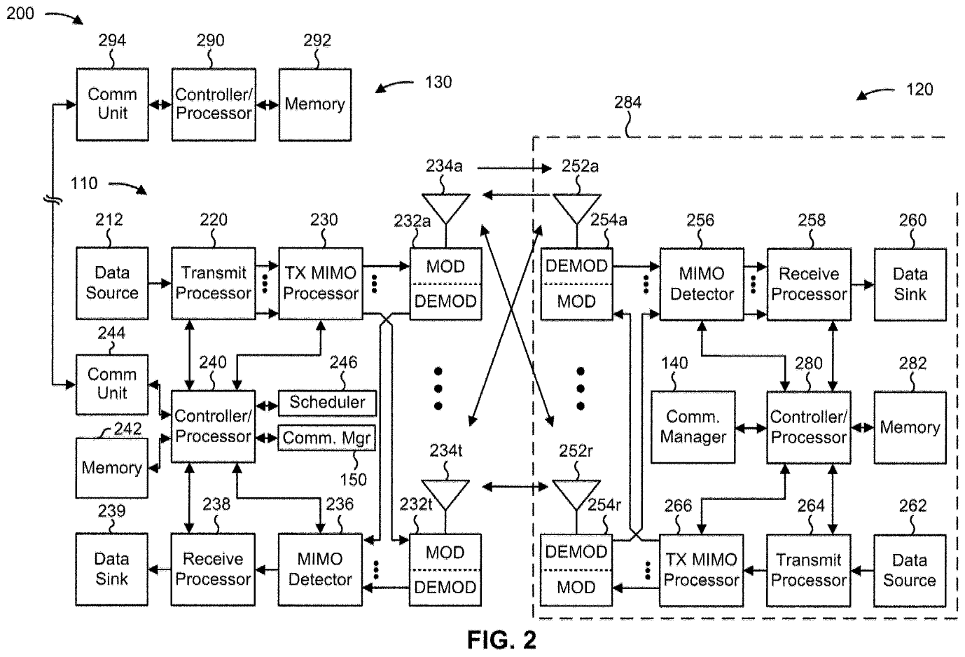

FIG. 2 is a diagram illustrating an example 200 of a network node 110 in communication with a UE 120 in a wireless network 100, in accordance with the present disclosure. The network node 110 may be equipped with a set of antennas 234a through 234t, such as T antennas (T≥1). The UE 120 may be equipped with a set of antennas 252a through 252r, such as R antennas (R≥1). The network node 110 of example 200 includes one or more radio frequency components, such as antennas 234 and a modem 232. In some examples, a network node 110 may include an interface, a communication component, or another component that facilitates communication with the UE 120 or another network node. Some network nodes 110 may not include radio frequency components that facilitate direct communication with the UE 120, such as one or more CUs, or one or more DUs.

At the network node 110, a transmit processor 220 may receive data, from a data source 212, intended for the UE 120 (or a set of UEs 120). The transmit processor 220 may select one or more modulation and coding schemes (MCSs) for the UE 120 based at least in part on one or more channel quality indicators (CQIs) received from that UE 120. The network node 110 may process (e.g., encode and modulate) the data for the UE 120 based at least in part on the MCS(s) selected for the UE 120 and may provide data symbols for the UE 120. The transmit processor 220 may process system information (e.g., for semi-static resource partitioning information (SRPI)) and control information (e.g., CQI requests, grants, and/or upper layer signaling) and provide overhead symbols and control symbols. The transmit processor 220 may generate reference symbols for reference signals (e.g., a cell-specific reference signal (CRS) or a demodulation reference signal (DMRS)) and synchronization signals (e.g., a primary synchronization signal (PSS) or a secondary synchronization signal (SSS)). A transmit (TX) multiple-input multiple-output (MIMO) processor 230 may perform spatial processing (e.g., precoding) on the data symbols, the control symbols, the overhead symbols, and/or the reference symbols, if applicable, and may provide a set of output symbol streams (e.g., T output symbol streams) to a corresponding set of modems 232 (e.g., T modems), shown as modems 232a through 232t. For example, each output symbol stream may be provided to a modulator component (shown as MOD) of a modem 232. Each modem 232 may use a respective modulator component to process a respective output symbol stream (e.g., for OFDM) to obtain an output sample stream. Each modem 232 may further use a respective modulator component to process (e.g., convert to analog, amplify, filter, and/or upconvert) the output sample stream to obtain a downlink signal. The modems 232a through 232t may transmit a set of downlink signals (e.g., T downlink signals) via a corresponding set of antennas 234 (e.g., T antennas), shown as antennas 234a through 234t.

At the UE 120, a set of antennas 252 (shown as antennas 252a through 252r) may receive the downlink signals from the network node 110 and/or other network nodes 110 and may provide a set of received signals (e.g., R received signals) to a set of modems 254 (e.g., R modems), shown as modems 254a through 254r. For example, each received signal may be provided to a demodulator component (shown as DEMOD) of a modem 254. Each modem 254 may use a respective demodulator component to condition (e.g., filter, amplify, downconvert, and/or digitize) a received signal to obtain input samples. Each modem 254 may use a demodulator component to further process the input samples (e.g., for OFDM) to obtain received symbols. A MIMO detector 256 may obtain received symbols from the modems 254, may perform MIMO detection on the received symbols if applicable, and may provide detected symbols. A receive processor 258 may process (e.g., demodulate and decode) the detected symbols, may provide decoded data for the UE 120 to a data sink 260, and may provide decoded control information and system information to a controller/processor 280. The term “controller/processor” may refer to one or more controllers, one or more processors, or a combination thereof. A channel processor may determine a reference signal received power (RSRP) parameter, a received signal strength indicator (RSSI) parameter, a reference signal received quality (RSRQ) parameter, and/or a CQI parameter, among other examples. In some examples, one or more components of the UE 120 may be included in a housing 284.

The network controller 130 may include a communication unit 294, a controller/processor 290, and a memory 292. The network controller 130 may include, for example, one or more devices in a core network. The network controller 130 may communicate with the network node 110 via the communication unit 294.

One or more antennas (e.g., antennas 234a through 234t and/or antennas 252a through 252r) may include, or may be included within, one or more antenna panels, one or more antenna groups, one or more sets of antenna elements, and/or one or more antenna arrays, among other examples. An antenna panel, an antenna group, a set of antenna elements, and/or an antenna array may include one or more antenna elements (within a single housing or multiple housings), a set of coplanar antenna elements, a set of non-coplanar antenna elements, and/or one or more antenna elements coupled to one or more transmission and/or reception components, such as one or more components of FIG. 2.

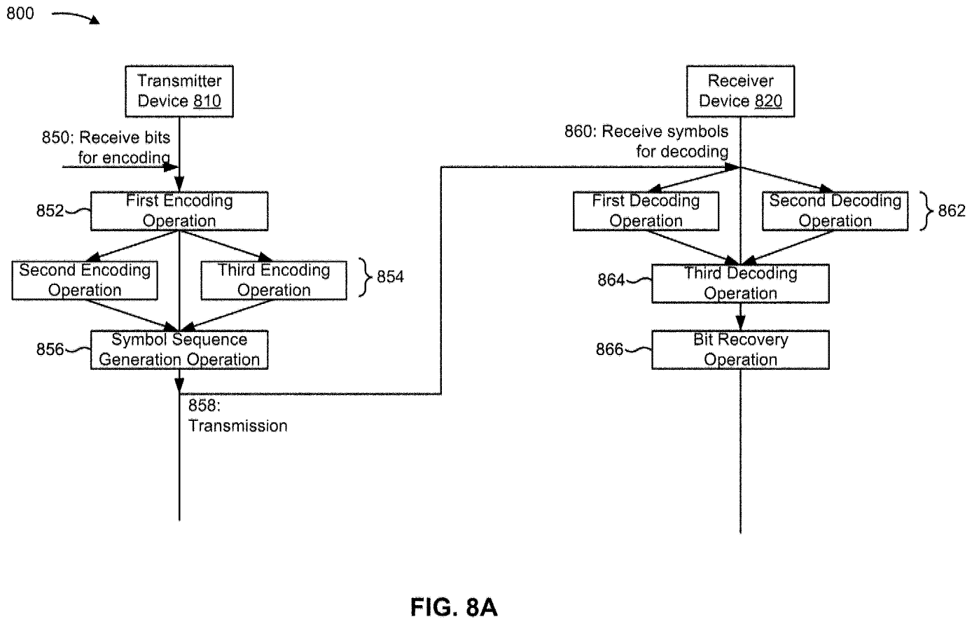

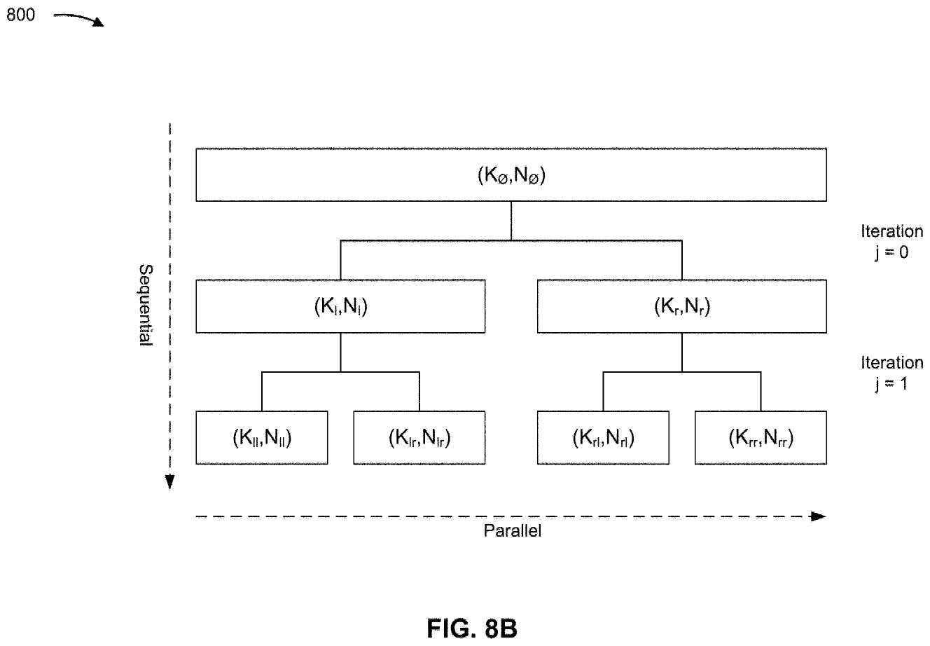

On the uplink, at the UE 120, a transmit processor 264 may receive and process data from a data source 262 and control information (e.g., for reports that include RSRP, RSSI, RSRQ, and/or CQI) from the controller/processor 280. The transmit processor 264 may generate reference symbols for one or more reference signals. The symbols from the transmit processor 264 may be precoded by a TX MIMO processor 266 if applicable, further processed by the modems 254 (e.g., for DFT-s-OFDM or CP-OFDM), and transmitted to the network node 110. In some examples, the modem 254 of the UE 120 may include a modulator and a demodulator. In some examples, the UE 120 includes a transceiver. The transceiver may include any combination of the antenna(s) 252, the modem(s) 254, the MIMO detector 256, the receive processor 258, the transmit processor 264, and/or the TX MIMO processor 266. The transceiver may be used by a processor (e.g., the controller/processor 280) and the memory 282 to perform aspects of any of the methods described herein (e.g., with reference to FIGS. 8A-12).

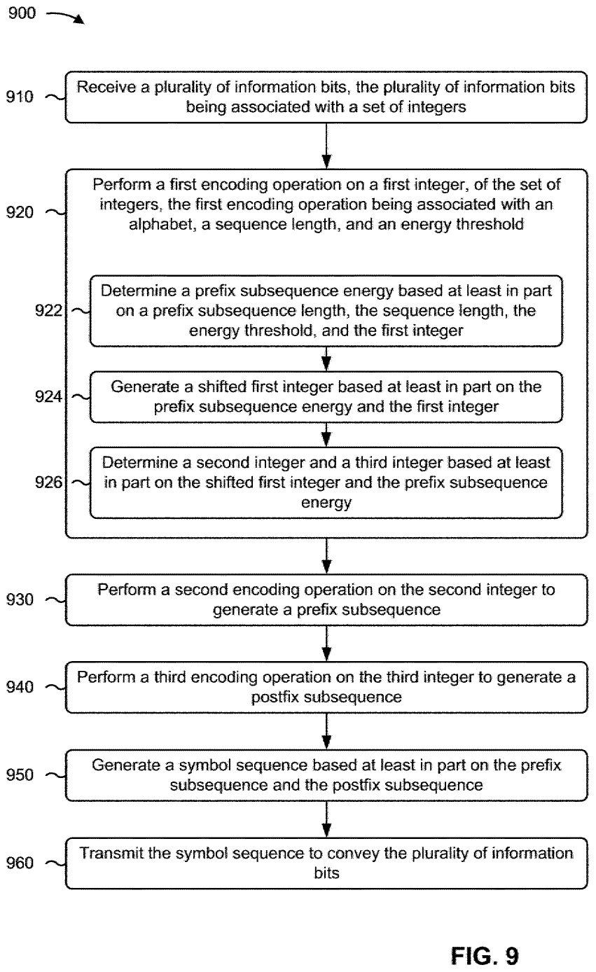

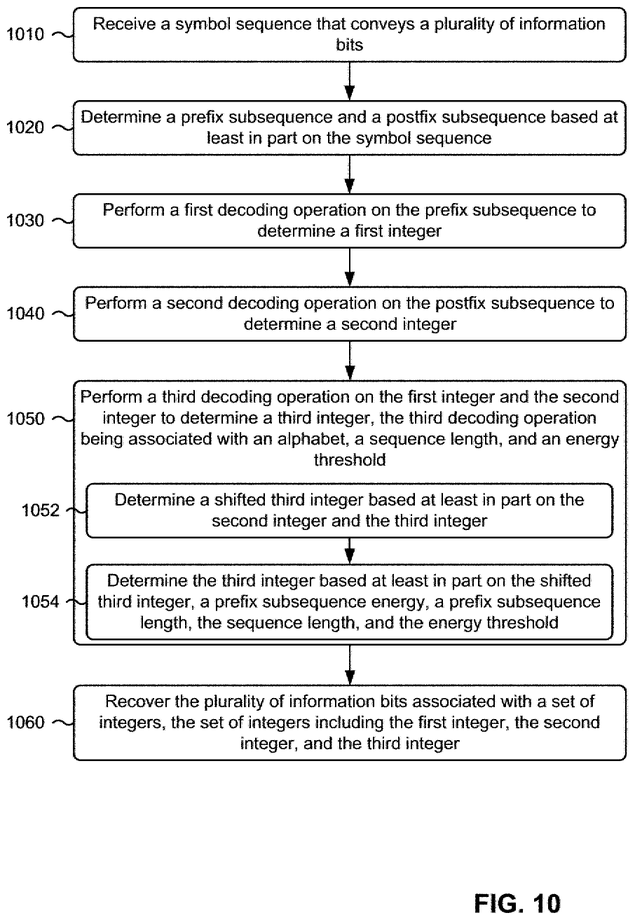

At the network node 110, the uplink signals from UE 120 and/or other UEs may be received by the antennas 234, processed by the modem 232 (e.g., a demodulator component, shown as DEMOD, of the modem 232), detected by a MIMO detector 236 if applicable, and further processed by a receive processor 238 to obtain decoded data and control information sent by the UE 120. The receive processor 238 may provide the decoded data to a data sink 239 and provide the decoded control information to the controller/processor 240. The network node 110 may include a communication unit 244 and may communicate with the network controller 130 via the communication unit 244. The network node 110 may include a scheduler 246 to schedule one or more UEs 120 for downlink and/or uplink communications. In some examples, the modem 232 of the network node 110 may include a modulator and a demodulator. In some examples, the network node 110 includes a transceiver. The transceiver may include any combination of the antenna(s) 234, the modem(s) 232, the MIMO detector 236, the receive processor 238, the transmit processor 220, and/or the TX MIMO processor 230. The transceiver may be used by a processor (e.g., the controller/processor 240) and the memory 242 to perform aspects of any of the methods described herein (e.g., with reference to FIGS. 8A-12). The controller/processor 240 of the network node 110, the controller/processor 280 of the UE 120, and/or any other component(s) of FIG. 2 may perform one or more techniques associated with energy based splitting and combining for probabilistic amplitude shaping based communication, as described in more detail elsewhere herein. In some aspects, the transmitter device or the receiver device described herein is the network node 110, is included in the network node 110, or includes one or more components of the network node 110 shown in FIG. 2. In some aspects, the transmitter device or the receiver device described herein is the UE 120, is included in the UE 120, or includes one or more components of the UE 120 shown in FIG. 2. For example, the controller/processor 240 of the network node 110, the controller/processor 280 of the UE 120, and/or any other component(s) of FIG. 2 may perform or direct operations of, for example, process 900 of FIG. 9, process 1000 of FIG. 10, and/or other processes as described herein. The memory 242 and the memory 282 may store data and program codes for the network node 110 and the UE 120, respectively. In some examples, the memory 242 and/or the memory 282 may include a non-transitory computer-readable medium storing one or more instructions (e.g., code and/or program code) for wireless communication. For example, the one or more instructions, when executed (e.g., directly, or after compiling, converting, and/or interpreting) by one or more processors of the network node 110 and/or the UE 120, may cause the one or more processors, the UE 120, and/or the network node 110 to perform or direct operations of, for example, process 900 of FIG. 9, process 1000 of FIG. 10, and/or other processes as described herein. In some examples, executing instructions may include running the instructions, converting the instructions, compiling the instructions, and/or interpreting the instructions, among other examples.

In some aspects, a transmitter device (e.g., the UE 120 or the network node 110) includes means for receiving a plurality of information bits, the plurality of information bits being associated with a set of integers; means for performing a first encoding operation on a first integer, of the set of integers, the first encoding operation being associated with an alphabet, a sequence length, and an energy threshold, and the means for performing the first encoding operation including: means for determining a prefix subsequence energy based at least in part on a prefix subsequence length, the sequence length, the energy threshold, and the first integer, means for generating a shifted first integer based at least in part on the prefix subsequence energy and the first integer, and means for determining a second integer and a third integer based at least in part on the shifted first integer and the prefix subsequence energy; means for performing a second encoding operation on the second integer to generate a prefix subsequence; means for performing a third encoding operation on the third integer to generate a postfix subsequence; means for generating a symbol sequence based at least in part on the prefix subsequence and the postfix subsequence; and/or means for transmitting the symbol sequence to convey the plurality of information bits. In some aspects, the means for the transmitter device to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246. In some aspects, the means for the transmitter device to perform operations described herein may include, for example, one or more of communication manager 140, antenna 252, modem 254, MIMO detector 256, receive processor 258, transmit processor 264, TX MIMO processor 266, controller/processor 280, or memory 282.

In some aspects, a receiver device (e.g., the UE 120 or the network node 110) includes means for receiving a symbol sequence that conveys a plurality of information bits; means for determining a prefix subsequence and a postfix subsequence based at least in part on the symbol sequence; means for performing a first decoding operation on the prefix subsequence to determine a first integer; means for performing a second decoding operation on the postfix subsequence to determine a second integer; means for performing a third decoding operation on the first integer and the second integer to determine a third integer, the third decoding operation being associated with an alphabet, a sequence length, and an energy threshold, and the means for performing the third decoding operation including: means for determining a shifted third integer based at least in part on the second integer and the third integer, and means for determining the third integer based at least in part on the shifted third integer, a prefix subsequence energy, a prefix subsequence length, the sequence length, and the energy threshold; and/or means for recovering the plurality of information bits associated with a set of integers, the set of integers including the first integer, the second integer, and the third integer. In some aspects, the means for the receiver device to perform operations described herein may include, for example, one or more of communication manager 150, transmit processor 220, TX MIMO processor 230, modem 232, antenna 234, MIMO detector 236, receive processor 238, controller/processor 240, memory 242, or scheduler 246. In some aspects, the means for the receiver device to perform operations described herein may include, for example, one or more of communication manager 140, antenna 252, modem 254, MIMO detector 256, receive processor 258, transmit processor 264, TX MIMO processor 266, controller/processor 280, or memory 282.

While blocks in FIG. 2 are illustrated as distinct components, the functions described above with respect to the blocks may be implemented in a single hardware, software, or combination component or in various combinations of components. For example, the functions described with respect to the transmit processor 264, the receive processor 258, and/or the TX MIMO processor 266 may be performed by or under the control of the controller/processor 280.

As indicated above, FIG. 2 is provided as an example. Other examples may differ from what is described with regard to FIG. 2.

Deployment of communication systems, such as 5G NR systems, may be arranged in multiple manners with various components or constituent parts. In a 5G NR system, or network, a network node, a network entity, a mobility element of a network, a RAN node, a core network node, a network element, a base station, or a network equipment may be implemented in an aggregated or disaggregated architecture. For example, a base station (such as a Node B (NB), an evolved NB (eNB), an NR base station, a 5G NB, an access point (AP), a TRP, or a cell, among other examples), or one or more units (or one or more components) performing base station functionality, may be implemented as an aggregated base station (also known as a standalone base station or a monolithic base station) or a disaggregated base station. “Network entity” or “network node” may refer to a disaggregated base station, or to one or more units of a disaggregated base station (such as one or more CUs, one or more DUs, one or more RUs, or a combination thereof).

An aggregated base station (e.g., an aggregated network node) may be configured to utilize a radio protocol stack that is physically or logically integrated within a single RAN node (e.g., within a single device or unit). A disaggregated base station (e.g., a disaggregated network node) may be configured to utilize a protocol stack that is physically or logically distributed among two or more units (such as one or more CUs, one or more DUs, or one or more RUs). In some examples, a CU may be implemented within a network node, and one or more DUs may be co-located with the CU, or alternatively, may be geographically or virtually distributed throughout one or multiple other network nodes. The DUs may be implemented to communicate with one or more RUs. Each of the CU, DU, and RU also can be implemented as virtual units, such as a virtual central unit (VCU), a virtual distributed unit (VDU), or a virtual radio unit (VRU), among other examples.

Base station-type operation or network design may consider aggregation characteristics of base station functionality. For example, disaggregated base stations may be utilized in an IAB network, an open radio access network (O-RAN (such as the network configuration sponsored by the O-RAN Alliance)), or a virtualized radio access network (vRAN, also known as a cloud radio access network (C-RAN)) to facilitate scaling of communication systems by separating base station functionality into one or more units that can be individually deployed. A disaggregated base station may include functionality implemented across two or more units at various physical locations, as well as functionality implemented for at least one unit virtually, which can enable flexibility in network design. The various units of the disaggregated base station can be configured for wired or wireless communication with at least one other unit of the disaggregated base station.

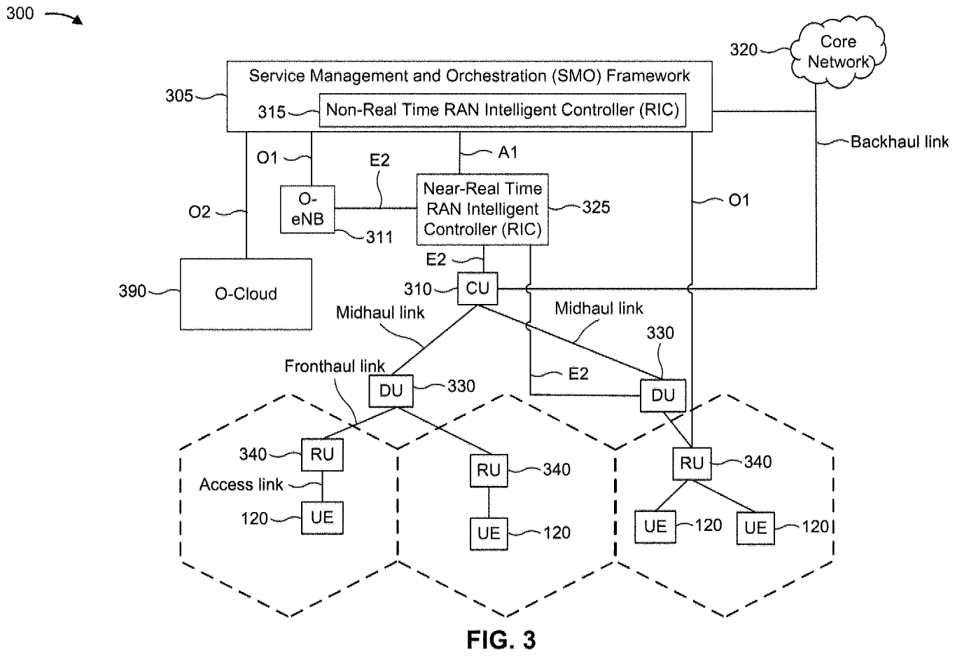

FIG. 3 is a diagram illustrating an example disaggregated base station architecture 300, in accordance with the present disclosure. The disaggregated base station architecture 300 may include a CU 310 that can communicate directly with a core network 320 via a backhaul link, or indirectly with the core network 320 through one or more disaggregated control units (such as a Near-RT RIC 325 via an E2 link, or a Non-RT RIC 315 associated with a Service Management and Orchestration (SMO) Framework 305, or both). A CU 310 may communicate with one or more DUs 330 via respective midhaul links, such as through F1 interfaces. Each of the DUs 330 may communicate with one or more RUs 340 via respective fronthaul links. Each of the RUs 340 may communicate with one or more UEs 120 via respective radio frequency (RF) access links. In some implementations, a UE 120 may be simultaneously served by multiple RUs 340.

Each of the units, including the CUS 310, the DUs 330, the RUs 340, as well as the Near-RT RICs 325, the Non-RT RICs 315, and the SMO Framework 305, may include one or more interfaces or be coupled with one or more interfaces configured to receive or transmit signals, data, or information (collectively, signals) via a wired or wireless transmission medium. Each of the units, or an associated processor or controller providing instructions to one or multiple communication interfaces of the respective unit, can be configured to communicate with one or more of the other units via the transmission medium. In some examples, each of the units can include a wired interface, configured to receive or transmit signals over a wired transmission medium to one or more of the other units, and a wireless interface, which may include a receiver, a transmitter or transceiver (such as an RF transceiver), configured to receive or transmit signals, or both, over a wireless transmission medium to one or more of the other units.

In some aspects, the CU 310 may host one or more higher layer control functions. Such control functions can include radio resource control (RRC) functions, packet data convergence protocol (PDCP) functions, or service data adaptation protocol (SDAP) functions, among other examples. Each control function can be implemented with an interface configured to communicate signals with other control functions hosted by the CU 310. The CU 310 may be configured to handle user plane functionality (for example, Central Unit-User Plane (CU-UP) functionality), control plane functionality (for example, Central Unit-Control Plane (CU-CP) functionality), or a combination thereof. In some implementations, the CU 310 can be logically split into one or more CU-UP units and one or more CU-CP units. A CU-UP unit can communicate bidirectionally with a CU-CP unit via an interface, such as the E1 interface when implemented in an O-RAN configuration. The CU 310 can be implemented to communicate with a DU 330, as necessary, for network control and signaling.

Each DU 330 may correspond to a logical unit that includes one or more base station functions to control the operation of one or more RUs 340. In some aspects, the DU 330 may host one or more of a radio link control (RLC) layer, a medium access control (MAC) layer, and one or more high physical (PHY) layers depending, at least in part, on a functional split, such as a functional split defined by the 3GPP. In some aspects, the one or more high PHY layers may be implemented by one or more modules for forward error correction (FEC) encoding and decoding, scrambling, and modulation and demodulation, among other examples. In some aspects, the DU 330 may further host one or more low PHY layers, such as implemented by one or more modules for a fast Fourier transform (FFT), an inverse FFT (iFFT), digital beamforming, or physical random access channel (PRACH) extraction and filtering, among other examples. Each layer (which also may be referred to as a module) can be implemented with an interface configured to communicate signals with other layers (and modules) hosted by the DU 330, or with the control functions hosted by the CU 310.

Each RU 340 may implement lower-layer functionality. In some deployments, an RU 340, controlled by a DU 330, may correspond to a logical node that hosts RF processing functions or low-PHY layer functions, such as performing an FFT, performing an iFFT, digital beamforming, or PRACH extraction and filtering, among other examples, based on a functional split (for example, a functional split defined by the 3GPP), such as a lower layer functional split. In such an architecture, each RU 340 can be operated to handle over the air (OTA) communication with one or more UEs 120. In some implementations, real-time and non-real-time aspects of control and user plane communication with the RU(s) 340 can be controlled by the corresponding DU 330. In some scenarios, this configuration can enable each DU 330 and the CU 310 to be implemented in a cloud-based RAN architecture, such as a vRAN architecture.

The SMO Framework 305 may be configured to support RAN deployment and provisioning of non-virtualized and virtualized network elements. For non-virtualized network elements, the SMO Framework 305 may be configured to support the deployment of dedicated physical resources for RAN coverage requirements, which may be managed via an operations and maintenance interface (such as an O1 interface). For virtualized network elements, the SMO Framework 305 may be configured to interact with a cloud computing platform (such as an open cloud (O-Cloud) platform 390) to perform network element life cycle management (such as to instantiate virtualized network elements) via a cloud computing platform interface (such as an O2 interface). Such virtualized network elements can include, but are not limited to, CUs 310, DUs 330, RUs 340, non-RT RICs 315, and Near-RT RICs 325. In some implementations, the SMO Framework 305 can communicate with a hardware aspect of a 4G RAN, such as an open eNB (O-eNB) 311, via an O1 interface. Additionally, in some implementations, the SMO Framework 305 can communicate directly with each of one or more RUs 340 via a respective O1 interface. The SMO Framework 305 also may include a Non-RT RIC 315 configured to support functionality of the SMO Framework 305.

The Non-RT RIC 315 may be configured to include a logical function that enables non-real-time control and optimization of RAN elements and resources, Artificial Intelligence/Machine Learning (AI/ML) workflows including model training and updates, or policy-based guidance of applications/features in the Near-RT RIC 325. The Non-RT RIC 315 may be coupled to or communicate with (such as via an A1 interface) the Near-RT RIC 325. The Near-RT RIC 325 may be configured to include a logical function that enables near-real-time control and optimization of RAN elements and resources via data collection and actions over an interface (such as via an E2 interface) connecting one or more CUs 310, one or more DUs 330, or both, as well as an O-eNB, with the Near-RT RIC 325.

In some implementations, to generate AI/ML models to be deployed in the Near-RT RIC 325, the Non-RT RIC 315 may receive parameters or external enrichment information from external servers. Such information may be utilized by the Near-RT RIC 325 and may be received at the SMO Framework 305 or the Non-RT RIC 315 from non-network data sources or from network functions. In some examples, the Non-RT RIC 315 or the Near-RT RIC 325 may be configured to tune RAN behavior or performance. For example, the Non-RT RIC 315 may monitor long-term trends and patterns for performance and employ AI/ML models to perform corrective actions through the SMO Framework 305 (such as reconfiguration via an O1 interface) or via creation of RAN management policies (such as A1 interface policies).

As indicated above, FIG. 3 is provided as an example. Other examples may differ from what is described with regard to FIG. 3.

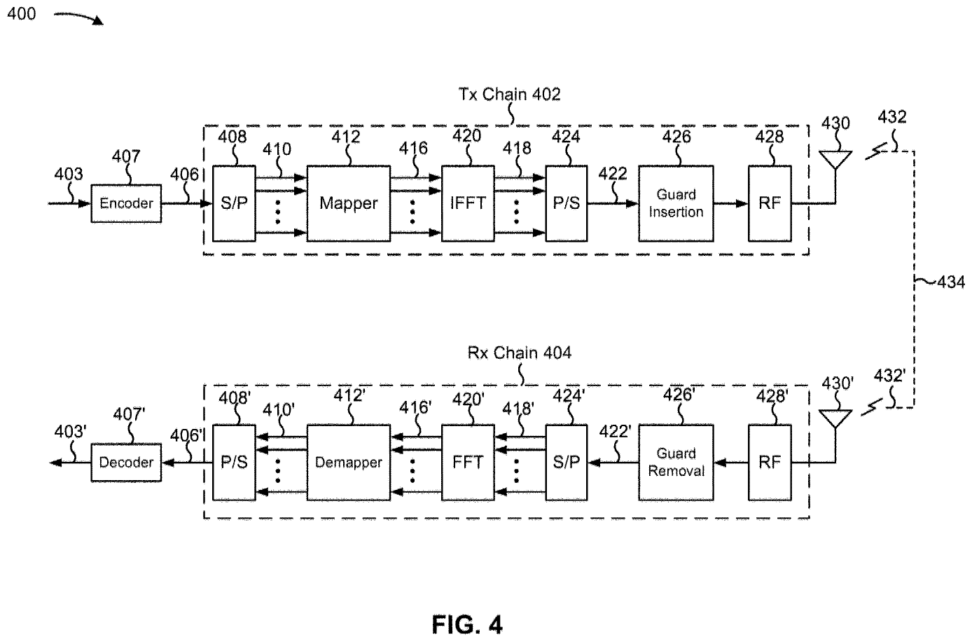

FIG. 4 is a diagram illustrating an example 400 of a transmit (Tx) chain 402 and a receive (Rx) chain 404 of a UE 120 in accordance with the present disclosure. In some examples, one or more components of Tx chain 402 may be implemented in transmit processor 264, TX MIMO processor 266, modem 254, or controller/processor 280, as described above in connection with FIG. 2. In some examples, Tx chain 402 may be implemented in UE 120 for transmitting data 406 (for example, uplink data, an uplink reference signal, or uplink control information) to a network node 110 on an uplink channel.

An encoder 407 may alter a signal (for example, a bitstream) 403 into data 406. Data 406 to be transmitted is provided from encoder 407 as input to a serial-to-parallel (S/P) converter 408. In some examples, S/P converter 408 may split the transmission data into N parallel data streams 410.

The N parallel data streams 410 may then be provided as input to a mapper 412. Mapper 412 may map the N parallel data streams 410 onto N constellation points. The mapping may be done using a modulation constellation, such as amplitude shift keying (ASK), binary phase-shift keying (BPSK), quadrature phase-shift keying (QPSK), 8 phase-shift keying (8PSK), or quadrature amplitude modulation (QAM), among other examples. Thus, mapper 412 may output N parallel symbol streams 416, each symbol stream 416 corresponding to one of N orthogonal subcarriers of an inverse fast Fourier transform (IFFT) component 420. These N parallel symbol streams 416 are represented in the frequency domain and may be converted into N parallel time domain sample streams 418 by IFFT component 420.

In some examples, N parallel modulations in the frequency domain correspond to N modulation symbols in the frequency domain, which are equal to N mapping and N-point IFFT in the frequency domain, which are equal to one (useful) OFDM symbol in the time domain, which are equal to N samples in the time domain. One OFDM symbol in the time domain, Ns, is equal to Ncp (the number of guard samples per OFDM symbol)+N (the number of useful samples per OFDM symbol).

The N parallel time domain sample streams 418 may be converted into an OFDM/OFDMA symbol stream 422 by a parallel-to-serial (P/S) converter 424. A guard insertion component 426 may insert a guard interval between successive OFDM/OFDMA symbols in the OFDM/OFDMA symbol stream 422. The output of guard insertion component 426 may then be upconverted to a desired transmit frequency band by an RF front end 428. An antenna 430 may then transmit the resulting signal 432.

In some examples, Rx chain 404 may utilize OFDM/OFDMA. In some examples, one or more components of Rx chain 404 may be implemented in receive processor 258, MIMO detector 256, modem 254, or controller/processor 280, as described above in connection with FIG. 2. In some examples, Rx chain 404 may be implemented in UE 120 for receiving data 406 (for example, downlink data, a downlink reference signal, or downlink control information) from a network node 110 on a downlink channel.

A transmitted signal 432 is shown traveling over a wireless channel 434 from Tx chain 402 to Rx chain 404. When a signal 432′ is received by an antenna 430′, the received signal 432′ may be downconverted to a baseband signal by an RF front end 428′. A guard removal component 426′ may then remove the guard interval that was inserted between OFDM/OFDMA symbols by guard insertion component 426.

The output of guard removal component 426′ may be provided to an S/P converter 424′. The output may include an OFDM/OFDMA symbol stream 422′, and S/P converter 424′ may divide the OFDM/OFDMA symbol stream 422′ into N parallel time-domain symbol streams 418′, each of which corresponds to one of the N orthogonal subcarriers. A FFT component 420′ may convert the N parallel time-domain symbol streams 418′ into the frequency domain and output N parallel frequency-domain symbol streams 416′.

A demapper 412′ may perform the inverse of the symbol mapping operation that was performed by mapper 412, thereby outputting N parallel data streams 410′. A P/S converter 408′ may combine the N parallel data streams 410′ into a single data stream 406′. Ideally, data stream 406′ corresponds to data 406 that was provided as input to Tx chain 402. Data stream 406′ may be decoded into a decoded data stream 403′ by decoder 407′.

As indicated above, FIG. 4 is provided as an example. Other examples may differ from what is described with regard to FIG. 4.

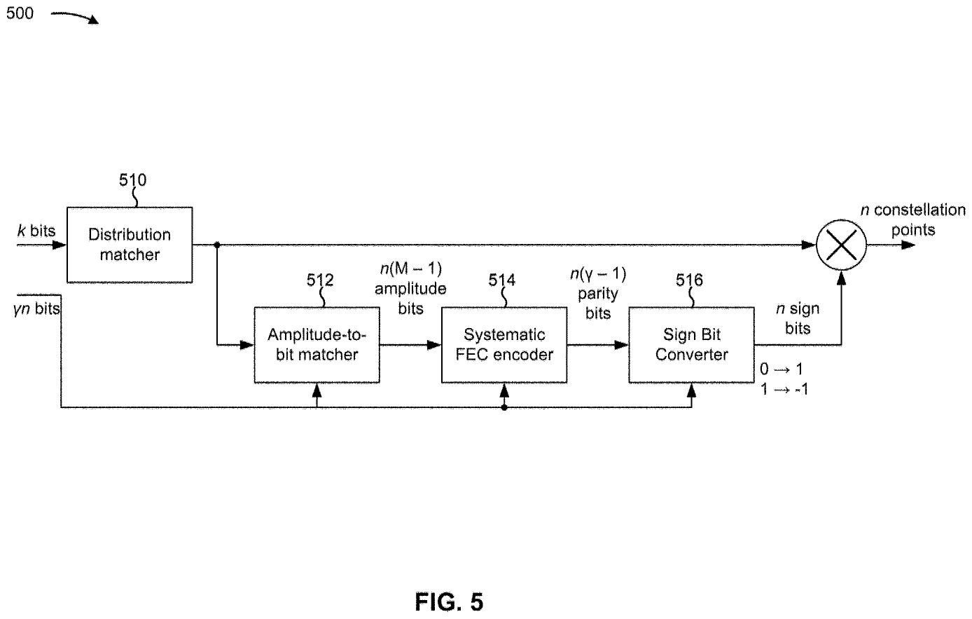

FIG. 5 is a diagram illustrating an example transmit chain 500 for probabilistic amplitude shaping in accordance with the present disclosure.

As shown in FIG. 5, the transmit chain 500 includes a distribution matcher 510, an amplitude-to-bit mapper 512, a systematic FEC encoder 514, and a sign bit converter 516. The transmit chain 500 may be used for, for example, ASK modulation with ASK constellations having a modulation order 2^{M}. An ASK constellation for the modulation order 2^{M} may include a set of constellation points {±1, ±3, . . . , ± (2^{M}−1)}. In some examples, the transmit chain 500 may have a transmission rate R_{c}=R_{dm}+γ, where R_{dm} represents a rate of the distribution matcher 510 and γ represents a set of parity bits that are added the k information bits that are to be encoded.

The ASK constellations may be associated with an amplitude alphabet of {1, 3, . . . , (2^{M}−1)}. The amplitude alphabet can include the set of possible constellation points (for example, without sign) from which the set of constellation points is generated. For example, an amplitude alphabet [symbol] ₘ={a₁, a₂, . . . , aₘ} of size m>1 may be configured for the transmit chain 500, with each element of [symbol] ₘ being referred to as a symbol. [symbol] ₘ may be constrained such that each element is ordered within [symbol] ₘ (for example, a₁<a₂< . . . <aₘ for any aᵢ). A symbol may have an energy E(aᵢ) for each value of i within the alphabet [symbol] ₘ. Based on the aforementioned constraint, symbol energies are ordered in correspondence with the ordering of symbols within [symbol] ₘ, such that 0≤E(aᵢ)<E(aᵢ₊₁). For a 2^{M}-ary ASK constellation, described in FIG. 5, [symbol] ₘ={1, 3, . . . , 2^{M}−1}, where m=2^{M}−1 and {−1, 1}× [symbol] ₘ corresponds to the 2^{M}-ary constellation. In this example, di=2i−1 so that a₁=1, a₂=3, . . . , aₘ=2^{M}−1, and so that, for each i, the energy E(aᵢ)=(2i−1)² of symbol aᵢ, in a first example, or

$$E ( {a}_{i} ) = \frac{i ( i - 1 )}{2} ,$$

in a second example. In these two examples, the second example is a rescaling of the (2i−1)² term in the first example.

For the alphabet [symbol] ₘ of size m with a symbol sequence s=(s₁, s₂, . . . , sₙ) of length n, where each element of s is selected from [symbol] ₘ, the energy E(s) is an accumulation (for example, a sum) of all symbol energies of the symbol sequence

$$E ( s ) = {\sum }_{l = 1}^{n} E ( {s}_{l} ) .$$

Accordingly, for the 2^{M}-ary ASK constellation with M=3; [symbol] ₘ={1, 3, 5, 7}; and m=4, an example symbol sequence (5, 1, 1, 3, 5, 7) with length n=6 can be configured. For the example symbol sequence, symbol energies can be determined, for E(1)=1, E(3)=9, E(5)=25 and E(7)=49, such that E(s)=2E(1)+E(3)+2E(5)+E(7)=2+9+50+49=110. In another example, for E(1)=0, E(3)=1, E(5)=3 and E(7)=6, the symbol energies can be determined as E(s)=2E(1)+E(3)+2E(5)+E(7)=13.

As further shown in FIG. 5, the distribution matcher 510 may receive k information bits and map the k information bits to n amplitude symbols. The distribution matcher 510 may have a rate R_{dm}=k/n. In some examples, the distribution matcher 510 maps the information bits to the amplitude symbols to achieve a non-uniform distribution over the amplitude symbols. The non-uniform distribution induced by the distribution matcher 510 may be closer to a capacity-achieving input distribution than is achieved by a uniform distribution. In other words, the non-uniform distribution induced by the distribution matcher 510 is a probability distribution (for example, a Maxwell-Boltzmann (MB) distribution) in an additive white Gaussian noise (AWGN) channel. The transmit chain 500 may pass the n amplitude symbols to the amplitude-to-bit mapper 512, which may map the n amplitude symbols to a set of n(M−1) amplitude bits. The transmit chain 500 may pass the n(M−1) amplitude bits and γn extra information bits (for example, FEC bits) to the systematic FEC encoder 514 for FEC encoding. In this example, the systematic FEC encoder 514 receives n(M−1+γ) bits as input with a rate of R_{c}=(M−1+γ)/M. The systematic FEC encoder 514 may generate a set of n(1−γ) parity bits at the rate R_{c}. The transmit chain 500 may pass the n(1−γ) parity bits and the γn extra information bits to the sign bit converter 516, which may generate a set of n sign bits. The sign bit converter 516 generates a sign bit “1” for a bit “0” and a sign bit “−1” for a bit “1”. The transmit chain 500 may perform pointwise multiplication to combine the n amplitude symbols with the n sign bits to generate a set of n constellation points.

As indicated above, FIG. 5 is provided as an example. Other examples may differ from what is described with regard to FIG. 5.

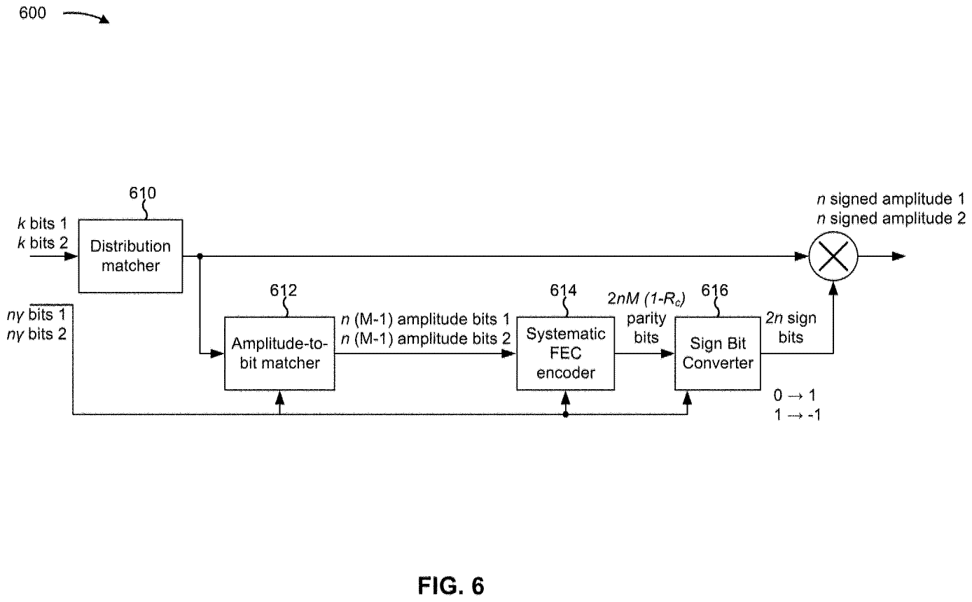

FIG. 6 is a diagram illustrating an example transmit chain 600 for probabilistic amplitude shaping in accordance with the present disclosure.

As shown in FIG. 6, the transmit chain 600 includes a distribution matcher 610, an amplitude-to-bit mapper 612, a systematic FEC encoder 614, and a sign bit converter 616. The transmit chain 600 may be used for, for example, QAM modulation with QAM constellations having a modulation order 2^{2M}. In such an example, a QAM constellation for the modulation order 2^{2M} may include a set of constellation points {+1, +3, . . . , ±(2^{M}−1)}×{±1, ±3, . . . , ±(2^{M}−1)}.

As further shown in FIG. 6, the distribution matcher 610 may receive a first set of k information bits and a second set of k information bits and maps the sets of k information bits to corresponding sets of n amplitude symbols. The transmit chain 600 may pass the sets of n amplitude symbols to the amplitude-to-bit mapper 612, which may map the sets of n amplitude symbols to a pair of sets of n(M−1) amplitude bits. The transmit chain 600 may pass the pair of sets of n(M−1) amplitude bits and a pair of sets of γn extra information bits to the systematic FEC encoder 614 for FEC encoding. The systematic FEC encoder 614 may have an FEC codeword length of n_{c}=n log₂ (2^{2M})=2 nM. In this example, the systematic FEC encoder 614 receives a total of 2 └nMRc┘ information bits as input in the form of two streams of n(M−1) amplitude bits from the information bits and two streams of extra information bits with each stream of extra information bits include nγ bits. The value for γ may be such that nγ=└nMRc┘−n (M−1). Accordingly, the total number of bits for transmission BT=2 (k+ └nMRc┘−n (M−1)). The systematic FEC encoder 614 may generate a set of 2 nM(1−R_{c}) parity bits at the rate R_{c}. The transmit chain 600 may pass the 2 nM(1−R_{c}) parity bits and the pair of sets of γn extra information bits to the sign bit converter 616, which may generate a set of 2n sign bits. The transmit chain 600 may perform pointwise multiplication to combine the sets of n amplitude symbols with the 2n sign bits to generate a pair of sets of n signed amplitudes.

As indicated above, FIG. 6 is provided as an example. Other examples may differ from what is described with regard to FIG. 6.

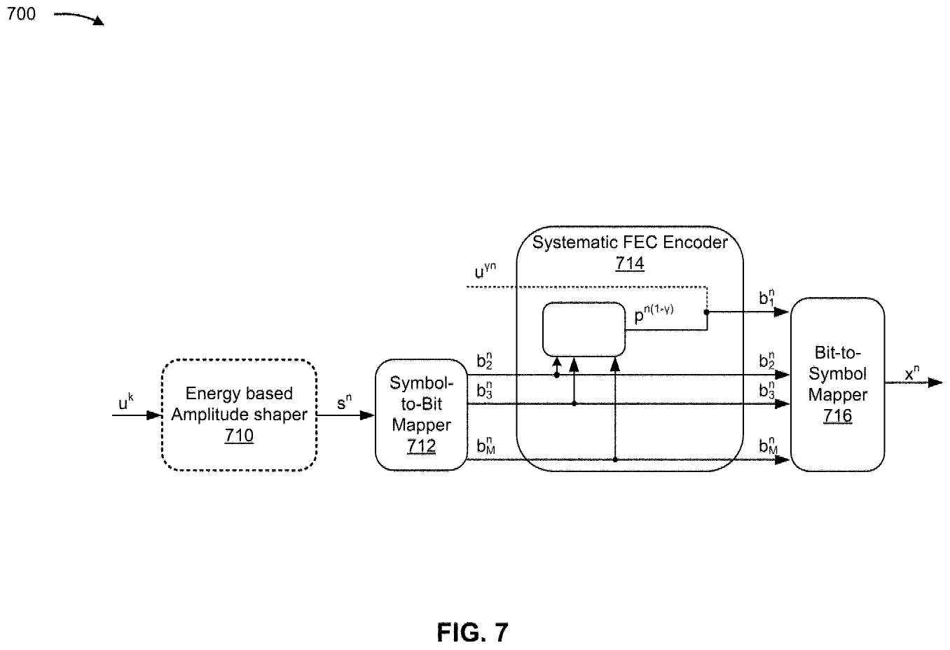

FIG. 7 is a diagram illustrating an example transmit chain 700 for energy-based probabilistic amplitude shaping in accordance with the present disclosure.

As shown in FIG. 7, the transmit chain 700 includes an energy-based amplitude shaper 710, a symbol-to-bit mapper 712, a systematic FEC encoder 714, and a bit-to-symbol mapper 716. The transmit chain 700 may be used for, for example, ASK modulation with ASK constellations having a modulation order 2^{M}. In such an example, an ASK constellation for the modulation order 2^{M} may include a set of constellation points {±1, +3, . . . , ±(2^{M}−1)} with an amplitude alphabet {1, 3, . . . , (2^{M}−1)}. In another example, the transmit chain 700 may be used for QAM modulation with a modulation order 2^{2M}, a set of constellation points {±1,+3, . . . , ±(2^{M}−1)}× {+1, +3, . . . , ±(2^{M}−1)}, and an amplitude alphabet {1, 3, . . . , 2^{M}−1}.

As further shown in FIG. 7, the energy-based amplitude shaper 710 may receive a sequence u^{k}=(u₁, u₂, . . . , uₖ) of k information bits. The sequence u^{k} represents a set of k information bits for encoding. The energy-based amplitude shaper 710 may determine a symbol sequence sⁿ with an energy E(sⁿ) that is constrained to be less than an energy threshold E. The symbol sequence sⁿ may represent a set of n amplitude symbols. In some examples, using an energy-based amplitude shaper can achieve a non-uniform symbol-wise marginal distribution of the n amplitude symbols that is closer to a capacity-achieving input distribution than when a uniform distribution is used as an input. The non-uniform symbol-wise marginal distribution may be the MB distribution for an AWGN channel. The symbol-to-bit mapper 712 may map the sequence sⁿ=(s₁, s₂, . . . , sₙ), which includes a set of n amplitude symbols, to (M−1) bit sequences of length n, denoted as

$$\{ {b}_{2}^{n} , {b}_{3}^{n} , … , {b}_{M}^{n} \} .$$

In other words, each of the n amplitude symbols corresponds to (M−1) bits, resulting in a total of n(M−1) amplitude bits.

The systematic FEC encoder 714 may receive the sets of bit sequences

$$\{ {b}_{2}^{n} , {b}_{3}^{n} , … , {b}_{M}^{n} \}$$

and a set of extra information bits u^{γn} (e.g., totaling n(M−1+γ)) for FEC encoding at a rate of R_{c}=(M−1+γ)/M. The systematic FEC encoder 714 generates an output set of n(1−γ) parity bits (or FEC bits) p^{n(1-γ)}, which maps to a bit sequence

$${b}_{1}^{n} .$$

The bit-to-symbol mapper 716 may receive the sets of bit sequences

$$\{ {b}_{2}^{n} , {b}_{3}^{n} , … , {b}_{M}^{n} \}$$

and the parity pit sequence

$${b}_{1}^{n}$$

and generate a set of symbols xⁿ. For Example, the bit sequence

$${b}_{1}^{n}$$

can be converted to n sign bits, which are pointwise multiplied with the n amplitude symbols in sⁿ. A resulting transmission rate Rₜ of the transmit chain 700 is Rₜ=Rₐₛ+γ, where Rₐₛ represents a rate of receiving amplitude symbols for encoding. It is desirable to achieve a non-uniform distribution over the amplitude symbols, which can be achieved through selection of the energy threshold E.

As indicated above, FIG. 7 is provided as an example. Other examples may differ from what is described with regard to FIG. 7.

As described above, an amplitude alphabet [symbol] ₘ={a₁, a₂, . . . , aₘ} for m>1 can be used when encoding a set of information bits to generate a set of symbols. The amplitude alphabet [symbol] ₘ may be ordered such that aᵢ<aᵢ₊₁ for any i∈{1, 2, . . . , m−1} (e.g., a₁<a₂< . . . <aₘ). Each symbol of the amplitude alphabet [symbol] ₘ has a symbol energy E(aᵢ) that is also ordered such that 0≤E(aᵢ)<E(aᵢ₊₁) for any i∈{1, 2, . . . , m−1} (e.g., E(a₁)<E(a₂)< . . . <E(aₘ)). One example of a constellation that can be used for symbol mapping is a 2^{M}-ary ASK constellation [symbol] ₘ={1, 3, . . . , 2^{M}−1}, where m=2^{M-1} and is based at least in part on the modulation order. Accordingly, aᵢ=2i−1, which results in a set of symbols @1=1, a₂=3, . . . , aₘ=2^{M}−1.

Given an amplitude alphabet [symbol] ₘ of size m, a sequence may be constructed s=(s₁, s₂, . . . , sₙ) of length n over the amplitude alphabet [symbol] ₘ. In other words, each element of the sequence s belongs to the amplitude alphabet [symbol] ₘ. The energy of the sequence s, denoted E(s) is a sum of symbol energies within the sequence s:

$$E ( s ) = {\sum }_{l = 1}^{n} E ( {s}_{l} )$$

where sₗ is an element of the sequence s (e.g., l ranges from 1 to n). A sequence quantity {s=(s₁, s₂, . . . , sₙ)|sᵢ∈ [symbol] ₘ, i∈{1, 2, . . . , n}, E(s)=E} represents a set of all sequences of length n over the amplitude alphabet [symbol] ₘ such that each sequence in the set has an energy equal to E. The sequence quantity is a value N^{[m]}(n, E) (e.g., a total quantity of distinct sequences in the above-mentioned set of all sequences), which may also be denoted “N(n, E)” or “N” depending on the context, where, for a given value of m, N(n, E) is a two-variable integer-valued function of n and E. Similarly, a cumulative sequence quantity N_{c}^{[m]}(n, E) (also denoted “N_{c}(n, E)” or “N_{c}” depending on the context) represents a set of all sequences of length n over [symbol] ₘ, such that each sequence in [symbol] (m, n, E) has an energy of at most E and is denoted as [symbol] (m, n, E) [symbol] {s|sᵢ∈ [symbol] ₘ, i∈{1, 2, . . . , n}, E(s)≤E}. N may relate to N_{c} according to a relationship:

$${N}_{c}^{[ m ]} ( n , E ) = {\sum }_{{E}^{′} = 0}^{E} {N}^{[ m ]} ( {n}^{′} , {E}^{′} ) {N}_{c}^{[ m ]} ( n - {n}^{′} , E - {E}^{′} )$$

where E(aₘ) represents a maximum symbol energy, such that 0≤E≤nE(aₘ) for 1≤n′≤n.

In some wireless communications, such as when higher-order modulations are used, a transmitter device may encode information bits using fixed constellation points. For example, fixed constellation points may be used with 16-QAM, 64-QAM, or 256-QAM, among other modulation and coding schemes. The fixed constellation points may each have an equal probability of being used for encoding the information bits. For AWGN channels, a shaping gap, which may be relative to a channel capacity or “Shannon capacity,” may be present that can asymptotically approach approximately 1.53 decibels (dB) for uniformly distributed channel inputs. The shaping gap may refer to a difference between a signal to noise ratio (SNR) to achieve a given rate with a given MCS and an SNR at which an optimal capacity-achieving scheme could operate, which may be the Shannon capacity or a “Shannon limit.”

Some techniques to reduce or close the shaping gap include geometric shaping and probabilistic shaping. In geometric shaping, a transmitter device may use equiprobable signaling with a non-uniform (for example, Gaussian-like) distribution of constellation points. In contrast, in probabilistic shaping, the transmitter device may use equidistant constellation points with non-uniform (for example, Gaussian-like) signal distribution. To perform probabilistic shaping, the transmitter device may determine an energy threshold E such that there is a non-uniform distribution over a set of amplitude symbols induced by an energy-based shaping scheme. If the non-uniform distribution is relatively different than an optimal MB distribution, the shaping gap may be excessively large, which may result in poor communication performance.

A probability distribution (such as an MB distribution) with a parameter ν (a non-negative real number) over an amplitude alphabet [symbol] ₘ results in a probability distribution of the form

$${p}_{v} ( a ) = \frac{1}{{z}_{v}} {e}^{- vE ( a )} ,$$

where a represents elements of [symbol] ₘ and A_{ν} is a normalizing constant. An optimal probability distribution over an ASK constellation, such as the ASK constellation described with reference to FIGS. 5 and 7, can exhibit a relatively large shaping gain over a uniform distribution for the same constellation. In other words, the uniform distribution has a shaping gap of some amount from the optimal probability distribution (for example, an MB distribution).

As described above, a set of encoded information bits may be associated with an amplitude alphabet [symbol] ₘ, a symbol sequence s, a sequence length n, and a total energy E. An energy threshold Ē may represent a constraint on the total energy E, such that [symbol] (m,n,Ē) can represent the set of all symbol sequences of length n and over an alphabet [symbol] ₘ such that the energy of each sequence is at most equal to an energy threshold Ē. A transmitter device may perform energy-based shaping, and may use, for the encoding, a direct energy-based arithmetic coding (AC) method or a two-stage peeling method. A distribution matcher of the transmitter device, such as distribution matchers 510 and 610 can implement one of the aforementioned example techniques. In such examples, a distribution mapper induces an injective mapping from the set of all 2^{k} possible information bit sequences to [symbol] (m,n,Ē). A consequence of such encoding is unique decodability is guaranteed at the receiver device by imposing conditions on k in terms of m, n, and Ē. However, the encoding methods described above are implemented as a serial process. For example, the underlying direct energy-based AC method is a serially implemented method, which may result in excess latency to encode and transmit latency-sensitive communications.

Some aspects described herein provide for low-latency energy-based probabilistic amplitude shaping. For example, some aspects described herein enable dividing of an encoding problem into a set of sub-encoding problems for parallel processing, which reduces a latency associated with generating a signal for transmission. Similarly, some aspects described herein may be applied to enable parallel decoding techniques, thereby reducing a latency associated with decoding of transmissions.

FIGS. 8A and 8B are diagrams of an example 800 associated with energy based splitting and combining for probabilistic amplitude shaping based communication, in accordance with the present disclosure. As shown in FIG. 8A, a transmitter device 810 may communicate with a receiver device 820. In some aspects, the transmitter device 810 or the receiver device 820 may include one or more of a network node 110 a UE 120 or a component thereof.

As further shown in FIG. 8A, and by reference number 850, the transmitter device 810 may receive a set of bits for encoding. For example, the transmitter device 810 may receive a plurality of information bits based at least in part on the plurality of information bits being generated by an application of the transmitter device 810. The plurality of information bits may represent a binary expansion of a first integer, described below.

As further shown in FIG. 8A, and by reference number 852, the transmitter device 810 may perform a first encoding operation. For example, the transmitter device 810 may perform the first encoding operation on the first integer K_{Ø}, of the set of integers, to determine a second integer Kₗ and a third integer Kᵣ of the set of integers. A first encoding problem includes associating the first integer K_{Ø} with a sequence quantity N_{Ø}, as described in more details below. Similarly, when the second integer and the third integer are determined from the first integer, the second integer and the third integer may be associated with sequence quantities Nₗ and Nᵣ, respectively. As shown in FIG. 8B, the transmitter device 810 performs a splitting operation on (K_{Ø}, N_{Ø}) to generate (Kₗ, Nₗ) and (Kᵣ, Nᵣ). In some aspects, K_{Ø} is an unsigned integer of k information bits, with K_{Ø}<N_{Ø}. Similarly, the second integer Kₗ is an unsigned integer representing a portion of a shifted first integer K_{ø}^{*}, the unsigned integer Kₗ being associated with a subset of sequences in [symbol] (m,n,Ē) (which may be referred to as “subsequences”), wherein each sequence, of the subset of sequences in [symbol] (m,n,Ē), has a respective length equal to n and a respective energy equal to Eₗ, and the subset of sequences in [symbol] (m,n,Ē) has a cardinality represented by N(nₗ, Eₗ). Additionally or alternatively, the sequence quantity N(nₗ, Eₗ) may be abbreviated as Nₗ. As described below, (Kₗ, Mₗ) may be further split into (Kₗₗ, Nₗₗ) and (Kₗᵣ, Mₗᵣ), wherein Kₗₗ may be referred to as a fourth integer and Kₗᵣ may be referred to as a fifth integer. Each one of the fourth integer Kₗₗ and the fifth integer Kₗᵣ represents a respective portion of a shifted second integer Kₗ^{*}. Additionally or alternatively, the fourth integer Kₗₗ is associated with a sub-subset of sequences in [symbol] (m,n,Ē) (which may be referred as “sub-subsequences”), wherein each sequence, of the sub-subset of sequences in [symbol] (m,n,Ē), has a respective length equal to nₗₗ and a respective energy equal to Eₗₗ, and the sub-subset of sequences in [symbol] (m,n,Ē) has a cardinality represented by a sequence quantity N(nₗₗ, Eₗₗ). Additionally or alternatively, the sequence quantity N(nₗₗ, Eₗₗ) may be abbreviated as Nₗₗ. The labels “l” and “r” (with an ordering l<r), used above, refer to a left branch and a right branch of a splitting operation (or sub-splitting operation). In other words, a set of subsequence labels {l, r} can be specified as a proxy for {(a₁, a₂, . . . , aⱼ)|aᵢ∈{l, r}, 1≤i≤}, with {l, r} 0=Ø and a lexicographical ordering among elements {l, r}). In other words, {l, r} 0=Ø, which corresponds to a null subsequence label for N_{Ø}, {l, r} 1={l, r}, which corresponds to subsequence labels for Nₗ and Nᵣ, {l, r}²={ll, lr, rl rr}, which corresponds to subsequence labels for Nₗₗ, Nₗᵣ, Nᵣₗ, and Nᵣᵣ, etc.

For any non-negative integer j and for e∈{l, r}^{j}, a notation e★l represents a “one-letter extension of e by 1” which is an element of {l, r}^{j+1}. For example, when e=(l, r, r), then e★l=(l, r, r, l). Further, J can represent a subdivision height for encoding, where/is a positive integer, 1≤J≤log₂ n. Each subdivision, as described below, is associated with a subdivision length, which can be selected from a family of subdivision lengths that is a set of non-negative integers {nₑ|e∈{l, r}^{j}, 0≤j≤J} for any j and e∈{l, r}^{j}. The family of subdivision lengths has a size nₑ≥0, where n_{e★l}+n_{e★r}=nₑ. Examples of the family of subdivision lengths satisfy n_{e★l}=┌nₑ/2┐ and n_{e★r}−nₑ−┌nₑ/2┐. When the sequence length n is a power of 2 so that n_{Ø}=n is a power of 2, the above equations simplify to n_{e★l}=nₑ/2 and n_{e★r}=nₑ/2; that is, each subdivision length, of the family of subdivision lengths, is a power of 2.

Returning to the first encoding operation, the transmitter device 810 may have inputs of an amplitude alphabet [symbol] ₘ, a subdivision height J, a family of subdivision lengths {nₑ|e∈{l, r}^{j}, 0≤j≤J}, and a plurality of information bits u₁, u₂, . . . , uₖ of length k for encoding, such that:

$${2}^{k} \leq {N}_{c}^{[ m ]} ( n , \overline{E} )$$

where Ē is an energy threshold, which may also be referred to as a maximum sequence energy. In a first phase of encoding, the transmitter device 810 performs an initialization, in which the transmitter device 810 initializes values to j=0, e=Ø, nₑ=n, E_{Ø}=Ē and N_{Ø}=N_{c}(n, Ē) and interprets the k information bits as a first (unsigned) integer K_{Ø}, where K_{Ø}<N_{Ø}.

In some aspect the transmitter device 810 may perform an iterative process for encoding. For example, the transmitter device 810 may iterate a set of steps from j=0 to j=J−1, as described below. In an iteration j, the transmitter device 810 enumerates the set {l, r}^{j}, where e is an element being enumerated and is associated with parameters nₑ, Eₑ and Kₑ. Here, if e≠(r, r, . . . , r) and e≠Ø, the transmitter device 810, in iteration j, determines a largest integer E, such that the inequality N̅_{E}≤Kₑ is satisfied, where:

$${\overline{N}}_{E} = {\sum }_{{E}^{′} = 0}^{E - 1} N ( {n}_{e * 1} , {E}^{′} ) N ( {n}_{e * r} , {E}_{e} - {E}^{′} )$$

wherein each N(n_{e★l}, E′) represents a cardinality of a respective total quantity of sequences (each sequence, of the respective total quantity of sequences, having a respective length equal to n_{e★l} and a respective energy equal to E′). Similarly, each N(n_{e★r}, Eₑ−E′) represents a cardinality of a respective total quantity of sequences (each sequence, of the respective total quantity of sequences, having a respective length equal to n_{e★r} and a respective energy equal to Eₑ−E′).

In the iteration j, the transmitter device 810 determines a prefix subsequence energy E_{e★l}=E, which is associated with a subsequence label e★1, and determines a postfix subsequence energy E_{e★r}=Eₑ−E, which is associated with a subsequence label e★r. The transmitter device 810 may determine the prefix subsequence energy based at least in part on a prefix subsequence length, a sequence length, a maximum sequence energy, and the first integer, and may associate the prefix subsequence energy to the subsequence label e★l. The transmitter device 810 may determine a sequence quantity N(n_{e★l}, E) based at least in part on n_{e★l} and the prefix subsequence energy E. The transmitter device 810 may abbreviate the sequence quantity N(n_{e★l}, E) as N_{e★l} (e.g., N_{e★l}=N(n_{e★l}, E)). The transmitter device 810 may determine a sequence quantity N(n_{e★r}, Eₑ−E) based at least in part on n_{e★r} and the postfix subsequence energy Eₑ−E. Additionally, the transmitter device 810 may abbreviate the sequence quantity N(n_{e★r}, Eₑ−E) as N_{e★r} (e.g., N_{e★r}=N(n_{e★r}, Eₑ−E), as described above).

The transmitter device 810 may use E_{e★l} as an energy for a subsequence associated with a subsequence label e★l, the subsequence having a length equal to n_{e★l}. In some aspects, the transmitter device 810 may determine a maximum postfix subsequence energy based at least in part on the prefix subsequence energy and the maximum sequence energy, as described above.

Alternatively, if e=(r, r, . . . , r) or e=Ø, the transmitter device 810, in iteration j, determines a largest integer E so that the inequality N̅_{E}≤Kₑ is satisfied, where:

$${\overline{N}}_{E} = {\sum }_{{E}^{′} = 0}^{E - 1} N ( {n}_{e * 1} , {E}^{′} ) {N}_{c} ( {n}_{e * r} , {E}_{e} - {E}^{′} )$$

wherein each N_{c}(n_{e★r}, Eₑ−E′) represents a cardinality of a respective total quantity of sequences (each sequence, of the respective total quantity of sequences, having a respective length equal to n_{e★r} and a respective energy less than or equal to Eₑ−E′). In other words, depending on whether e≠(r, r, . . . , r) and e≠Ø, the transmitter device 810 may determine N̅_{E} based at least in part on a plurality of sequence quantities and/or a plurality of cumulative sequence quantities.

In some aspects, the transmitter device 810 may determine a range of non-negative integers, each representing a candidate energy associated with the prefix subsequence energy. The transmitter device 810 may further determine a plurality of sequence quantities based at least in part on the range of non-negative integers. In some aspects, each sequence quantity, of the plurality of sequence quantities associated with the encoding procedure, corresponds to a cardinality of a first set of subsequences over the alphabet [symbol] ₘ, with each subsequence having a length equal to a prefix subsequence length and having an energy equal to an integer of a range of non-negative integers. Similarly, each cumulative sequence quantity corresponds to a respective integer of a range of non-negative integers and to a cardinality of a second set of subsequences over the amplitude alphabet [symbol] ₘ with lengths equal to a difference between the sequence length and the prefix subsequence length and an energy less than or equal to a difference between a maximum sequence energy and an integer of the range of non-negative integers.

Based at least in part on determining the value of N̅_{E}, the transmitter device 810 may, in iteration j, determine a shifted integer (e.g., a shifted value of the first integer Kₑ) as

$${K}_{e}^{*} = {K}_{e} - {\overline{N}}_{E} ( or {K}_{ϕ}^{*} = {K}_{ϕ} - {\overline{N}}_{E}$$

in one example encoding operation). In some aspects, the transmitter device 810 may determine and/or use a value of N(n, [symbol] ) and/or N_{c}(n, [symbol] ) for encoding, where 0≤n≤n and 0≤n≤Ē. For example, n=n_{e★l} or n=n_{e★r}, and [symbol] =E′ or [symbol] =Eₑ−E′ where n and [symbol] are variables and the sequence quantities and cumulative sequence quantities (e.g., values thereof) can be obtained by a plurality of different techniques. The transmitter device 810 may determine the quantities using a computation technique (e.g., using recursive definition), a configured look-up table storing values (e.g., that are dependent on m), and/or using an approximation method (e.g., that may be dependent on m).

In some aspects, the transmitter device 810 may use an energy range restriction technique with functions of n and [symbol] : E⁻(n, [symbol] ), E⁺(n, [symbol] ) and E_{c}⁻(n, [symbol] ),

$${E}_{c}^{+} ( 𝓃 , \text{?} )$$

to restrict subsequence energy selections in, for example, a first phase of encoding. The functions are used to enumerate an energy-based group of underlying subdivided subsequences:

$${E}_{e * 1} ∈ [ {E}^{-} ( {n}_{e} , {E}_{e} ) , {E}^{+} ( {n}_{e} , {E}_{e} ) ] if e \neq {\{ r \}}^{j}$$

$${E}_{e * 1} ∈ [ {E}_{c}^{-} ( {n}_{e} , {E}_{e} ) , {E}_{c}^{+} ( {n}_{e} , {E}_{e} ) ] otherwise$$

thereby reducing a calculation complexity. For example, for n_{e★l} and E′, as described above, in the above restricted range, the transmitter device 810 can determine N(n_{e★l}, E′) and N(n_{e★r}, Eₑ−E′) (or N_{c}(n_{e★r}, Eₑ−E′)) with a reduced range of E′. Although using an approximation or energy range restriction can result in one or more small errors or degradations (e.g., a loss in a quantity of uniquely decodable bits k), the transmitter device 810 and the receiver device 820 may calibrate for such an error or degradation by using parity bits, redundancy, or some other technique.

In some aspects, the transmitter device 810 may determine each sequence quantity of a plurality of sequence quantities (e.g., N(nₑ₊ₗ, E′) and N(n_{e★r}, Eₑ−E′)) and/or each cumulative sequence quantity of a plurality of cumulative sequence quantities (e.g., N_{c}(n_{e★r}, Eₑ−E′)) using a particular procedure. For example, the transmitter device 810 may approximate a logarithm of each sequence quantity or cumulative sequence and exponentiate the approximated logarithm of each sequence quantity or cumulative sequence quantity. Additionally, or alternatively, the transmitter device 810 may use recursive definition technique, access a look-up table storing sequence quantity or cumulative sequence quantity values (e.g., using m to identify a value in the look-up table), use another approximation technique.

In some aspects, the transmitter device 810 may determine a prefix subsequence index K_{e★l} (e.g., during the iteration j). For example, the transmitter device 810 may determine the prefix subsequence index K_{e★l}, which is associated with the subsequence label e★l, as:

$${K}_{e * 1} = ⌊ \frac{{K}_{e}^{*}}{{N}_{e * r}} ⌋ .$$

Similarly, the transmitter device 810 may determine a postfix subsequence index K_{e★r} based at least in part on the prefix subsequence index. For example, the transmitter device 810 may determine the postfix subsequence index K_{e★r}, which is associated with the subsequence label e★r, as:

$${K}_{e * r} = {K}_{e}^{*} - {N}_{e * r} {K}_{e * 1} .$$

The transmitter device 810 may determine a respective prefix subsequence index, a respective prefix subsequence energy, and a respective postfix subsequence index, a respective postfix subsequence energy (or a respective maximum postfix subsequence energy) for each subsequence label e, enumerated from {l, r}^{j} until each element e of {l, r}^{j} has been enumerated to complete the iteration j. FIG. 8B shows an example of a first two iterations of a first phase of encoding (e.g., an example where J=2). For example, for j=0, (K_{Ø}, N_{Ø}) is split to generate (Kₗ, Nₗ) and (Kᵣ, Nᵣ). Similarly, during j=1, there is an enumeration of {l, r}¹, where on a left branch (e=l), (Kₑ, Nₑ)=(Kₗ, Nₗ) is split to (K_{e★1}, N_{e★1})=(Kₗₗ, Nₗₗ) and (K_{e★r}, N_{e★r})=(Kₗᵣ, Nₗᵣ); and, where on the right branch (e=r), (Kₑ, Nₑ)=(Kᵣ, Nᵣ) is split to (K_{e★l}, N_{e★l})=(Kᵣₗ, Nᵣₗ) and (Ker, N_{e★r})=(Kᵣᵣ, Nᵣᵣ), as described in more detail herein.

Accordingly, a first encoding operation, performed by the transmitter device 810, may correspond to a first split from (K_{Ø}, N_{Ø}) to (Kₗ, Nₗ) and (Kᵣ, Nᵣ), in which an original encoding problem is to encode an index K_{Ø} (e.g., a first integer) to a sequence of length n_{Ø}=n and energy at most E_{Ø}=Ē. After the first iteration of a first phase of encoding, the encoding problem is split into two sub-problems and the energy for each sub-problem is split, such that a first sub-problem is to encode a first subsequence index K_{Ø★l}=Kₗ (e.g., a second integer) to a prefix subsequence of length n_{Ø★l} and energy equal to a prefix subsequence energy E_{Ø★1}, and a second sub-problem is to encode a second subsequence index K_{Ø}+r=Kᵣ (e.g., a third integer) to a postfix subsequence of length n_{Ø★r} and energy less than or equal to a maximum postfix subsequence energy E_{Ø★r}. In contrast, a second encoding operation and a third encoding operation, performed by the transmitter device, as described in more detail below, may correspond to further splits in a left branch and a right branch (e.g., from (Kₗ, Nₗ) to (Kₗₗ, Nₗₗ) and (Kₗᵣ, Nₗᵣ) and from (Kᵣ, Nᵣ) to (Kᵣₗ, Nᵣₗ) and (Kᵣᵣ, Nᵣᵣ).

As further shown in FIG. 8A, and by reference number 854, the transmitter device 810 may perform the above-mentioned second encoding operation and third encoding operation. For example, the transmitter device 810 may perform the second operation on the second integer Kₗ, of the set of integers, to generate a prefix subsequence. Additionally, or alternatively, the transmitter device 810 may perform the third encoding operation on the third integer Kᵣ, of the set of integers, to generate a postfix subsequence. In some aspects, the transmitter device 810 may perform the second encoding operation and the third encoding operation in parallel. For example, the transmitter device 810 may perform at least a portion of the second encoding operation concurrently with performing at least a portion of the third encoding operation.

In some aspects, the transmitter device 810 may further split the second integer Kₗ and/or the third integer Kᵣ. For example, as shown in FIG. 8B, the transmitter device 810 may split an encoding problem of (Kₗ, Nₗ) into a set of parallel encoding problems (Kₗₗ, Nₗₗ) and (Kₗᵣ, Nₗᵣ). Similarly, the transmitter device 810 may split the encoding problem (Kᵣ, Nᵣ) into a set of parallel encoding problems (Kᵣₗ, Nᵣₗ) and (Kᵣᵣ, Nᵣᵣ). In these examples, the transmitter device 810 may perform one or more of the further encoding problems (e.g., (Kₗₗ, Nₗₗ) and (Kₗᵣ, Nₗᵣ)) in parallel (e.g., at least partially concurrently). Although some aspects are described herein in terms of splitting into two parallel encoding problems and/or two layers of encoding problem splits, it is contemplated that there may be additional splitting for higher quantities of parallel encoding problems (e.g., 2^{J} encoding sub-problems for some J>2, with each of the encoding sub-problems corresponding to a respective index e in {l, r}) and/or additional splitting for additional layers of encoding problem splits.

In some aspects, to complete, for example, the second encoding operation, the third encoding operation, or a 2^{J}-th encoding problem, the transmitter device 810 may perform an encoding operation to encode a subsequence index Kₑ (where e is an element in {l, r}^{J}) to a sequence from among Nₑ sequences, where each sequence includes elements of the amplitude alphabet [symbol] ₘ, each sequence has a length of nₑ, and each sequence has an energy less than or equal to Eₑ, thereby generating a sequence se, which is one of the Nₑ sequences satisfying a set of properties (e.g., sₑ has a length of nₑ, an energy of Eₑ if e≠{r}^{J} or an energy less than or equal to Eₑ if e={r}^{J}). In this case, the 2^{J} encoding problems are decoupled (e.g., independent of each other), thereby enabling parallel processing.

As further shown in FIG. 8A, and by reference number 856, the transmitter device 810 may perform a symbol sequence generation operation based at least in part on the prefix subsequence and the postfix subsequence. For example, the transmitter device 810 may generate a symbol sequence sⁿ, from subsequences se generated during the above-mentioned encoding operations, such that for example sⁿ=(s_{(l, l, . . . , l)}, s_{(l, l, . . . , r)}, . . . , s_{(r, r, . . . , r)}) In some aspects, the transmitter device 810 may concatenate a plurality of sub-sequences into a sequence (e.g., the prefix subsequence) or the postfix sequence and concatenate a plurality of sequences to form a single sequence (e.g., the symbol sequence). In this case, the transmitter device 810 can use the symbol sequence for transmission.

As further shown in FIG. 8A, and by reference number 858, the transmitter device 810 may transmit the symbol sequence to the receiver device 820. For example, the transmitter device 810 may modulate the symbol sequence onto a carrier and transmit the symbol sequence to the receiver device 820 using a set of resources of the carrier (e.g., time resources, frequency resources, and spatial resources).

As further shown in FIG. 8A, and by reference number 860, the receiver device 820 may receive the symbols for decoding. For example, the receiver device 820 may receive a symbol sequence, on a carrier, that conveys a plurality of information bits. In this case, the receiver device 820 may recover the prefix subsequence and the postfix subsequence from the received transmission of the symbol sequence.

As further shown in FIG. 8A, and by reference number 862, the receiver device 820 may perform a first decoding operation and a second decoding operation. For example, the receiver device 820 may perform a set of concurrent decoding procedures on a set of sub-problems. In this case, the receiver device 820 may perform the first decoding operation on the prefix subsequence to determine a first integer (e.g., which may correspond to the third integer Kₗ, described above), and may perform the second decoding operation on the postfix subsequence to determine a second integer (e.g., which may correspond to the second integer Kᵣ, described above). In other words, the first and second decoding operations reverse the second and third encoding operations, described above.

In some aspects, the receiver device 820 may perform a first phase of decoding, which includes the first decoding operation, the second decoding operation, or a 2^{J}-th decoding operation. For example, the receiver device 820 may take inputs of an alphabet [symbol] ₘ, a sequence length n, an energy threshold Ē, a subdivision height J, a set of subdivision lengths {nₑ|e∈{l, r}^{j}, 0≤j≤J}, and a received symbol sequence ŝⁿ=(ŝ₁, ŝ₂, . . . , ŝₙ)∈ [symbol] (m, n, Ē), and may subdivide the received symbol sequence according to a family of subdivision lengths ŝⁿ=(ŝ_{(l, l, . . . , l)}, ŝ_{(l, l, . . . , r)}, . . . , ŝ_{(r, r, . . . , r)})=(ŝₑ_{₁}, ŝₑ_{₂}, . . . , ŝₑ_{₂}_{^{J}}) for encoding as a set of 2^{J} decoupled decoding sub-problems (e.g., for concurrent processing). Each of the 2′ decoding sub-problems corresponds to an encoding sub-problem described above. In some aspects, to determine an energy associated with the decoding sub-problems (e.g., a prefix subsequence energy or a postfix subsequence energy), the receiver device 820 may sum energies of elements associated with the decoding sub-problems. Based on completing the set of decoding sub-problems, the receiver device 820 may determine a subsequence index \hat{K}ₑ.

As further shown in FIG. 8A, and by reference number 864, the receiver device 820 may perform a third decoding operation. For example, the receiver device 820 may perform the third decoding operation to determine a shifted third integer (e.g., which may correspond to the shifted first integer described above) and, from the shifted third integer, a third integer (e.g., which may correspond to the first integer K_{Ø}, described above). In other words, the third decoding operation reverses the first encoding operation, described above. In some aspects, the receiver device 820 may perform a second phase of decoding. In this second phase of decoding, the receiver device 820 performs an iterative process on subsequence indices of \hat{K}ₑ for all e∈{l, r}^{J} from the first phase of decoding, with j initialized as j=J−1 for/iterations with the value of j being decreased by 1 after each iteration (until j=0). In other words, the iterative process of the first phase of decoding proceeds in reverse relative to the iterative process of the first phase of encoding. In this case, the receiver device 820, in an iteration j, determines a subsequence energy Eₑ=E(ŝₑ); determines a prefix subsequence energy E_{e★l}=E(ŝ_{e★1}) and an integer N̅_{E}_{_{e★l}}; and determines a postfix subsequence quantity N_{e★r}=N(n_{e★r}, Eₑ−E_{e★l}). Further, the receiver device 820 determines an integer \hat{K}ₑ^{*}=\hat{K}_{e★r}+N_{e★r}\hat{K}_{e★l} based at least in part on N_{e★r}, the prefix subsequence index \hat{K}_{e★l}, and the postfix subsequence index \hat{K}_{e★r}. Based at least in part on determining \hat{K}ₑ^{*}, the receiver device 820 determines subsequence index \hat{K}ₑ=\hat{K}₃^{*}+N̅_{E}_{_{e★l}} and continues the iterative process by enumerating a next element e of {l, r}j, as described above, until all elements e are enumerated. In this case, if all \hat{K}ₑ are decoded correctly for all e∈{l, r}^{J} from the first phase of decoding, which is the case when ŝⁿ=sⁿ, the decoded index \hat{K}_{Ø} is the same as K_{Ø} which corresponds to the information bits.

As further shown in FIG. 8A, and by reference number 866, the receiver device may perform a bit recovery operation. For example, the receiver device may recover the set of bits of the bit sequence u^{k}=(u₁, u₂, . . . , uₖ) from the symbol sequence sⁿ=(s₁, s₂, . . . , sₙ) in [symbol] (m, n, E) based at least in part on determining the third integer.

As indicated above, FIGS. 8A and 8B are provided as examples. Other examples may differ from what is described with respect to FIGS. 8A and 8B.

FIG. 9 is a diagram illustrating an example process 900 performed, for example, by a transmitter device, in accordance with the present disclosure. Example process 900 is an example where the transmitter device (e.g., a UE 120, a network node 110, or the transmitter device 810, among other examples) performs operations associated with energy based splitting and combining for probabilistic amplitude shaping based communication.

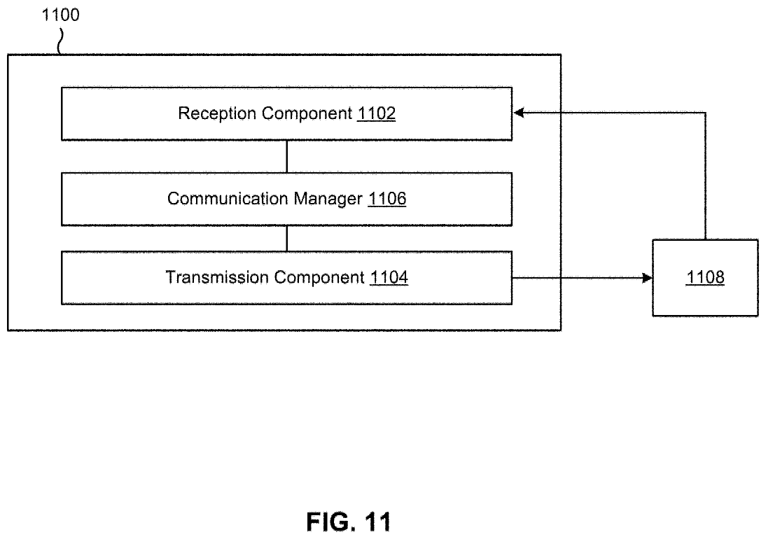

As shown in FIG. 9, in some aspects, process 900 may include receiving a plurality of information bits, the plurality of information bits being associated with a set of integers (block 910). For example, the transmitter device (e.g., using reception component 1102 and/or communication manager 1106, depicted in FIG. 11) may receive a plurality of information bits, the plurality of information bits being associated with a set of integers, as described above.

As further shown in FIG. 9, in some aspects, process 900 may include performing a first encoding operation on a first integer, of the set of integers, the first encoding operation being associated with an alphabet, a sequence length, and an energy threshold (block 920). In some aspects, the first encoding operation of process 900 may include determining a prefix subsequence energy based at least in part on a prefix subsequence length, the sequence length, the energy threshold, and the first integer (block 922). In some aspects, the first encoding operation of process 900 may include generating a shifted first integer based at least in part on the prefix subsequence energy and the first integer (block 924). In some aspects, the first encoding operation of process 900 may include determining a second integer and a third integer based at least in part on the shifted first integer and the prefix subsequence energy (block 926). For example, the transmitter device (e.g., using communication manager 1106, depicted in FIG. 11) may perform a first encoding operation on a first integer, of the set of integers, the first encoding operation being associated with an alphabet, a sequence length, and an energy threshold, and the first encoding operation including: determining a prefix subsequence energy based at least in part on a prefix subsequence length, the sequence length, the energy threshold, and the first integer, generating a shifted first integer based at least in part on the prefix subsequence energy and the first integer, and determining a second integer and a third integer based at least in part on the shifted first integer and the prefix subsequence energy, as described above.

As further shown in FIG. 9, in some aspects, process 900 may include performing a second encoding operation on the second integer to generate a prefix subsequence (block 930). For example, the transmitter device (e.g., using communication manager 1106, depicted in FIG. 11) may perform a second encoding operation on the second integer to generate a prefix subsequence, as described above.

As further shown in FIG. 9, in some aspects, process 900 may include performing a third encoding operation on the third integer to generate a postfix subsequence (block 940). For example, the transmitter device (e.g., using communication manager 1106, depicted in FIG. 11) may perform a third encoding operation on the third integer to generate a postfix subsequence, as described above.

As further shown in FIG. 9, in some aspects, process 900 may include generating a symbol sequence based at least in part on the prefix subsequence and the postfix subsequence (block 950). For example, the transmitter device (e.g., using communication manager 1106, depicted in FIG. 11) may generate a symbol sequence based at least in part on the prefix subsequence and the postfix subsequence, as described above.

As further shown in FIG. 9, in some aspects, process 900 may include transmitting the symbol sequence to convey the plurality of information bits (block 960). For example, the transmitter device (e.g., using transmission component 1104 and/or communication manager 1106, depicted in FIG. 11) may transmit the symbol sequence to convey the plurality of information bits, as described above.

Process 900 may include additional aspects, such as any single aspect or any combination of aspects described below and/or in connection with one or more other processes described elsewhere herein.

In a first aspect, determining the second integer and the third integer comprises determining the second integer based at least in part on the shifted first integer, the prefix subsequence length, and the prefix subsequence energy, and determining the third integer based at least in part on the second integer, the prefix subsequence length, the prefix subsequence energy, the sequence length, and the energy threshold.

In a second aspect, alone or in combination with the first aspect, process 900 includes determining a maximum postfix subsequence energy based at least in part on the prefix subsequence energy and the energy threshold.

In a third aspect, alone or in combination with one or more of the first and second aspects, the maximum postfix subsequence energy is equal to a difference between the energy threshold and the prefix subsequence energy.

In a fourth aspect, alone or in combination with one or more of the first through third aspects, the prefix subsequence has a length equal to the prefix subsequence length and has an energy equal to the prefix subsequence energy.

In a fifth aspect, alone or in combination with one or more of the first through fourth aspects, the postfix subsequence has a length equal to a difference between the sequence length and the prefix subsequence length and has an energy less than or equal to the maximum postfix subsequence energy.

In a sixth aspect, alone or in combination with one or more of the first through fifth aspects, performing the first encoding operation comprises identifying a range of non-negative integers, wherein each integer, of the range of nonnegative integers, comprises a candidate energy associated with the prefix subsequence energy, determining a plurality of sequence quantities, wherein each sequence quantity, of the plurality of sequence quantities, corresponds to a respective integer of the range of non-negative integers, a sequence quantity, of the plurality of sequence quantities, corresponds to a cardinality of a first set of subsequences over the alphabet, each subsequence, of the first set of subsequences, having a length equal to the prefix subsequence length, and having an energy equal to an integer of the range of non-negative integers, determining a plurality of cumulative sequence quantities, wherein each cumulative sequence quantity, of the plurality of cumulative sequence quantities, corresponds to a respective integer of the range of nonnegative integers, a cumulative sequence quantity, of the plurality of cumulative sequence quantities, corresponds to a cardinality of a second set of subsequences over the alphabet, each subsequence, of the second set of subsequences, having a length equal to a difference between the sequence length and the prefix subsequence length, and having an energy at most equal to a difference between a maximum sequence energy and the integer of the range of nonnegative integers, partitioning a first interval into a plurality of subintervals based at least in part on the plurality of sequence quantities and the plurality of cumulative sequence quantities, each subinterval, of the plurality of subintervals, corresponding to a respective sequence quantity of the plurality of sequence quantities and a respective cumulative sequence quantity of the plurality of cumulative sequence quantities, and determining a subinterval, of the plurality of subintervals, based at least in part on identifying that the first integer is a member of the subinterval, and determining the prefix subsequence energy based at least in part on identifying the integer, of the range of non-negative integers, that corresponds to the subinterval.

In a seventh aspect, alone or in combination with one or more of the first through sixth aspects, determining the plurality of sequence quantities comprises approximating a logarithm of each sequence quantity of the plurality of sequence quantities, and exponentiating the logarithm of each sequence quantity of the plurality of sequence quantities.

In an eighth aspect, alone or in combination with one or more of the first through seventh aspects, determining the plurality of cumulative sequence quantities comprises approximating a logarithm of each cumulative sequence quantity of the plurality of cumulative sequence quantities, and exponentiating the logarithm of each cumulative sequence quantity of the plurality of cumulative sequence quantities.

In a ninth aspect, alone or in combination with one or more of the first through eighth aspects, generating the shifted first integer is based at least in part on the first integer, the plurality of sequence quantities, and the plurality of cumulative sequence quantities.

In a tenth aspect, alone or in combination with one or more of the first through ninth aspects, the second integer is less than the sequence quantity, of the plurality of sequence quantities, and wherein the third integer is less than the cumulative sequence quantity, of the plurality of cumulative sequence quantities.

In an eleventh aspect, alone or in combination with one or more of the first through tenth aspects, the second encoding operation is performed in parallel with performing the third encoding operation.

In a twelfth aspect, alone or in combination with one or more of the first through eleventh aspects, the symbol sequence has a length equal to the sequence length and has an energy at most equal to the energy threshold, and each element of the symbol sequence is included in the alphabet.

In a thirteenth aspect, alone or in combination with one or more of the first through twelfth aspects, the sequence length is a power of 2, and the prefix subsequence length is a power of 2.

In a fourteenth aspect, alone or in combination with one or more of the first through thirteenth aspects, the plurality of information bits corresponds to a binary expansion of the first integer.

In a fifteenth aspect, alone or in combination with one or more of the first through fourteenth aspects, the energy threshold is based at least in part on the sequence length and a normalized energy threshold.

In a sixteenth aspect, alone or in combination with one or more of the first through fifteenth aspects, performing the second encoding operation comprises: determining a plurality of sub-subsequence energies based at least in part on the second integer, the prefix subsequence length, and the prefix subsequence energy; determining a plurality of integers based at least in part on the second plurality of sub-subsequence energies and the second integer, wherein each integer, of the second plurality of integers, corresponds to a respective sub-subsequence energy, of the second plurality of sub-subsequence energies; encoding each integer, of the plurality of integers, into a respective sub-subsequence, of a plurality of sub-subsequences, wherein each sub-subsequence, of the plurality of sub-subsequences, has an energy equal to a respective sub-subsequence energy, of the of sub-subsequence energies; and concatenating the plurality of sub-subsequences, wherein the prefix subsequence is based at least in part on the concatenating.

In a seventeenth aspect, alone or in combination with one or more of the first through sixteenth aspects, performing the third encoding operation comprises: determining a plurality of sub-subsequence energies based at least in part on the third integer and the maximum postfix subsequence energy; determining a plurality of integers based at least in part on the plurality of sub-subsequence energies and the third integer, wherein each integer, of the plurality of integers, corresponds to a respective sub-subsequence energy, of the third plurality of sub-subsequence energies; encoding each integer, of the plurality of integers, into a respective sub-subsequence, of a plurality of sub-subsequences, wherein each sub-subsequence, of the plurality of sub-subsequences, has an energy less than or equal to a respective sub-subsequence energy, of the plurality of sub-subsequence energies; and concatenating the plurality of sub-subsequences, wherein the postfix subsequence is based at least in part on the concatenating.

Although FIG. 9 shows example blocks of process 900, in some aspects, process 900 may include additional blocks, fewer blocks, different blocks, or differently arranged blocks than those depicted in FIG. 9. Additionally, or alternatively, two or more of the blocks of process 900 may be performed in parallel.

FIG. 10 is a diagram illustrating an example process 1000 performed, for example, by a receiver device, in accordance with the present disclosure. Example process 1000 is an example where the receiver device (e.g., a UE 120, a network node 110, or a receiver device 820) performs operations associated with energy based splitting and combining for probabilistic amplitude shaping based communication.

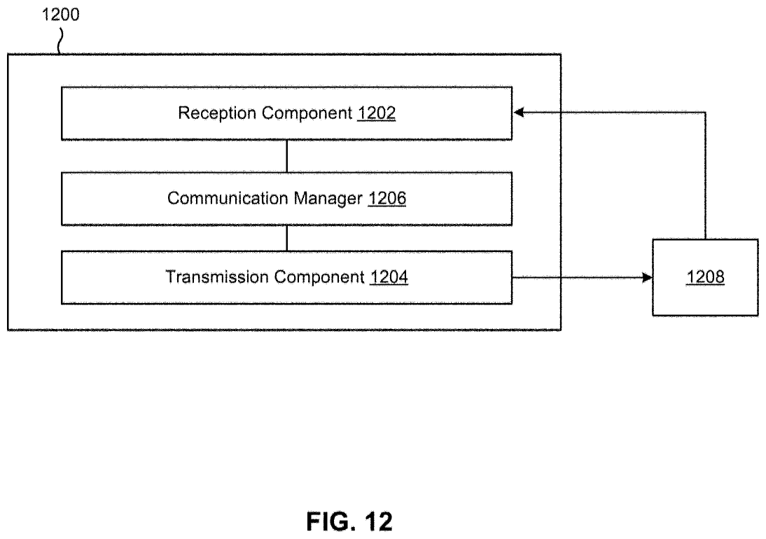

As shown in FIG. 10, in some aspects, process 1000 may include receiving a symbol sequence that conveys a plurality of information bits (block 1010). For example, the receiver device (e.g., using reception component 1202 and/or communication manager 1206, depicted in FIG. 12) may receive a symbol sequence that conveys a plurality of information bits, as described above.

As further shown in FIG. 10, in some aspects, process 1000 may include determining a prefix subsequence and a postfix subsequence based at least in part on the symbol sequence (block 1020). For example, the receiver device (e.g., using communication manager 1206, depicted in FIG. 12) may determine a prefix subsequence and a postfix subsequence based at least in part on the symbol sequence, as described above.

As further shown in FIG. 10, in some aspects, process 1000 may include performing a first decoding operation on the prefix subsequence to determine a first integer (block 1030). For example, the receiver device (e.g., using communication manager 1206, depicted in FIG. 12) may perform a first decoding operation on the prefix subsequence to determine a first integer, as described above.

As further shown in FIG. 10, in some aspects, process 1000 may include performing a second decoding operation on the postfix subsequence to determine a second integer (block 1040). For example, the receiver device (e.g., using communication manager 1206, depicted in FIG. 12) may perform a second decoding operation on the postfix subsequence to determine a second integer, as described above.

As further shown in FIG. 10, in some aspects, process 1000 may include performing a third decoding operation on the first integer and the second integer to determine a third integer, the third decoding operation being associated with an alphabet, a sequence length, and an energy threshold (block 1050). In some aspects, the third decoding operation of process 1000 may include determining a shifted third integer based at least in part on the second integer and the third integer (block 1052). In some aspects, the third decoding operation of process 1000 may include determining the third integer based at least in part on the shifted third integer, a prefix subsequence energy, a prefix subsequence length, the sequence length, and the energy threshold (block 1054). For example, the receiver device (e.g., using communication manager 1206, depicted in FIG. 12) may perform a third decoding operation on the first integer and the second integer to determine a third integer, the third decoding operation being associated with an alphabet, a sequence length, and an energy threshold, and the third decoding operation including: determining a shifted third integer based at least in part on the second integer and the third integer, and determining the third integer based at least in part on the shifted third integer, a prefix subsequence energy, a prefix subsequence length, the sequence length, and the energy threshold, as described above.

As further shown in FIG. 10, in some aspects, process 1000 may include recovering the plurality of information bits associated with a set of integers, the set of integers including the first integer, the second integer, and the third integer (block 1060). For example, the receiver device (e.g., using communication manager 1206, depicted in FIG. 12) may recover the plurality of information bits associated with a set of integers, the set of integers including the first integer, the second integer, and the third integer, as described above.

Process 1000 may include additional aspects, such as any single aspect or any combination of aspects described below and/or in connection with one or more other processes described elsewhere herein.

In a first aspect, the prefix subsequence has a length equal to the prefix subsequence length and has an energy equal to the prefix subsequence energy.

In a second aspect, alone or in combination with the first aspect, the first decoding operation is performed in parallel with performing the second decoding operation.

In a third aspect, alone or in combination with one or more of the first and second aspects, the symbol sequence has a length equal to the sequence length and has an energy less than or equal to the energy threshold, and each element of the symbol sequence is included in the alphabet.

In a fourth aspect, alone or in combination with one or more of the first through third aspects, the sequence length is a power of 2, and the prefix subsequence length is a power of 2.

In a fifth aspect, alone or in combination with one or more of the first through fourth aspects, determining the shifted third integer comprises determining the shifted third integer based at least in part on the prefix subsequence length, the prefix subsequence energy, the sequence length, and the energy threshold.

In a sixth aspect, alone or in combination with one or more of the first through fifth aspects, process 1000 includes determining the prefix subsequence energy based at least in part on a set of energies associated with the prefix subsequence.

Although FIG. 10 shows example blocks of process 1000, in some aspects, process 1000 may include additional blocks, fewer blocks, different blocks, or differently arranged blocks than those depicted in FIG. 10. Additionally, or alternatively, two or more of the blocks of process 1000 may be performed in parallel.

FIG. 11 is a diagram of an example apparatus 1100 for wireless communication, in accordance with the present disclosure. The apparatus 1100 may be a transmitter device, or a transmitter device may include the apparatus 1100. For example, the apparatus 1100 may be, may include, or may be included in a UE 120, a network node 110, or a transmitter device 810, among other examples. In some aspects, the apparatus 1100 includes a reception component 1102, a transmission component 1104, and/or a communication manager 1106, which may be in communication with one another (for example, via one or more buses and/or one or more other components). In some aspects, the communication manager 1106 is the communication manager 140/150 described in connection with FIG. 1. As shown, the apparatus 1100 may communicate with another apparatus 1108, such as a UE or a network node (such as a CU, a DU, an RU, or a base station), using the reception component 1102 and the transmission component 1104.

In some aspects, the apparatus 1100 may be configured to perform one or more operations described herein in connection with FIGS. 8A-8B. Additionally, or alternatively, the apparatus 1100 may be configured to perform one or more processes described herein, such as process 900 of FIG. 9. In some aspects, the apparatus 1100 and/or one or more components shown in FIG. 11 may include one or more components of the transmitter device described in connection with FIG. 2. Additionally, or alternatively, one or more components shown in FIG. 11 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 1102 may receive communications, such as reference signals, control information, data communications, or a combination thereof, from the apparatus 1108. The reception component 1102 may provide received communications to one or more other components of the apparatus 1100. In some aspects, the reception component 1102 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1100. In some aspects, the reception component 1102 may include one or more antennas, a modem, a demodulator, a MIMO detector, a receive processor, a controller/processor, a memory, or a combination thereof, of the transmitter device described in connection with FIG. 2.

The transmission component 1104 may transmit communications, such as reference signals, control information, data communications, or a combination thereof, to the apparatus 1108. In some aspects, one or more other components of the apparatus 1100 may generate communications and may provide the generated communications to the transmission component 1104 for transmission to the apparatus 1108. In some aspects, the transmission component 1104 may perform signal processing on the generated communications (such as filtering, amplification, modulation, digital-to-analog conversion, multiplexing, interleaving, mapping, or encoding, among other examples), and may transmit the processed signals to the apparatus 1108. In some aspects, the transmission component 1104 may include one or more antennas, a modem, a modulator, a transmit MIMO processor, a transmit processor, a controller/processor, a memory, or a combination thereof, of the transmitter device described in connection with FIG. 2. In some aspects, the transmission component 1104 may be co-located with the reception component 1102 in a transceiver.

The communication manager 1106 may support operations of the reception component 1102 and/or the transmission component 1104. For example, the communication manager 1106 may receive information associated with configuring reception of communications by the reception component 1102 and/or transmission of communications by the transmission component 1104. Additionally, or alternatively, the communication manager 1106 may generate and/or provide control information to the reception component 1102 and/or the transmission component 1104 to control reception and/or transmission of communications.

The reception component 1102 may receive a plurality of information bits, the plurality of information bits being associated with a set of integers. The communication manager 1106 may perform a first encoding operation on a first integer, of the set of integers, the first encoding operation being associated with an alphabet, a sequence length, and an energy threshold, and the first encoding operation including determining a prefix subsequence energy based at least in part on a prefix subsequence length, the sequence length, the energy threshold, and the first integer, generating a shifted first integer based at least in part on the prefix subsequence energy and the first integer, and determining a second integer and a third integer based at least in part on the shifted first integer and the prefix subsequence energy. The communication manager 1106 may perform a second encoding operation on the second integer to generate a prefix subsequence. The communication manager 1106 may perform a third encoding operation on the third integer to generate a postfix subsequence. The communication manager 1106 may generate a symbol sequence based at least in part on the prefix subsequence and the postfix subsequence. The transmission component 1104 may transmit the symbol sequence to convey the plurality of information bits. The communication manager 1106 may determine a maximum postfix subsequence energy based at least in part on the prefix subsequence energy and the energy threshold.

The number and arrangement of components shown in FIG. 11 are provided as an example. In practice, there may be additional components, fewer components, different components, or differently arranged components than those shown in FIG. 11. Furthermore, two or more components shown in FIG. 11 may be implemented within a single component, or a single component shown in FIG. 11 may be implemented as multiple, distributed components. Additionally, or alternatively, a set of (one or more) components shown in FIG. 11 may perform one or more functions described as being performed by another set of components shown in FIG. 11.

FIG. 12 is a diagram of an example apparatus 1200 for wireless communication, in accordance with the present disclosure. The apparatus 1200 may be a receiver device, or a receiver device may include the apparatus 1200. For example, the apparatus 1200 may be, may include, or may be included in a UE 120, a network node 110, or a receiver device 820, among other examples. In some aspects, the apparatus 1200 includes a reception component 1202, a transmission component 1204, and/or a communication manager 1206, which may be in communication with one another (for example, via one or more buses and/or one or more other components). In some aspects, the communication manager 1206 is the communication manager 140/150 described in connection with FIG. 1. As shown, the apparatus 1200 may communicate with another apparatus 1208, such as a UE or a network node (such as a CU, a DU, an RU, or a base station), using the reception component 1202 and the transmission component 1204.

In some aspects, the apparatus 1200 may be configured to perform one or more operations described herein in connection with FIGS. 8A-8B. Additionally, or alternatively, the apparatus 1200 may be configured to perform one or more processes described herein, such as process 1000 of FIG. 10. In some aspects, the apparatus 1200 and/or one or more components shown in FIG. 12 may include one or more components of the receiver device described in connection with FIG. 2. Additionally, or alternatively, one or more components shown in FIG. 12 may be implemented within one or more components described in connection with FIG. 2. Additionally, or alternatively, one or more components of the set of components may be implemented at least in part as software stored in a memory. For example, a component (or a portion of a component) may be implemented as instructions or code stored in a non-transitory computer-readable medium and executable by a controller or a processor to perform the functions or operations of the component.

The reception component 1202 may receive communications, such as reference signals, control information, data communications, or a combination thereof, from the apparatus 1208. The reception component 1202 may provide received communications to one or more other components of the apparatus 1200. In some aspects, the reception component 1202 may perform signal processing on the received communications (such as filtering, amplification, demodulation, analog-to-digital conversion, demultiplexing, deinterleaving, de-mapping, equalization, interference cancellation, or decoding, among other examples), and may provide the processed signals to the one or more other components of the apparatus 1200. In some aspects, the reception component 1202 may include one or more antennas, a modem, a demodulator, a MIMO detector, a receive processor, a controller/processor, a memory, or a combination thereof, of the receiver device described in connection with FIG. 2.

The transmission component 1204 may transmit communications, such as reference signals, control information, data communications, or a combination thereof, to the apparatus 1208. In some aspects, one or more other components of the apparatus 1200 may generate communications and may provide the generated communications to the transmission component 1204 for transmission to the apparatus 1208. In some aspects, the transmission component 1204 may perform signal processing on the generated communications (such as filtering, amplification, modulation, digital-to-analog conversion, multiplexing, interleaving, mapping, or encoding, among other examples), and may transmit the processed signals to the apparatus 1208. In some aspects, the transmission component 1204 may include one or more antennas, a modem, a modulator, a transmit MIMO processor, a transmit processor, a controller/processor, a memory, or a combination thereof, of the receiver device described in connection with FIG. 2. In some aspects, the transmission component 1204 may be co-located with the reception component 1202 in a transceiver.

The communication manager 1206 may support operations of the reception component 1202 and/or the transmission component 1204. For example, the communication manager 1206 may receive information associated with configuring reception of communications by the reception component 1202 and/or transmission of communications by the transmission component 1204. Additionally, or alternatively, the communication manager 1206 may generate and/or provide control information to the reception component 1202 and/or the transmission component 1204 to control reception and/or transmission of communications.

The reception component 1202 may receive a symbol sequence that conveys a plurality of information bits. The communication manager 1206 may determine a prefix subsequence and a postfix subsequence based at least in part on the symbol sequence. The communication manager 1206 may perform a first decoding operation on the prefix subsequence to determine a first integer. The communication manager 1206 may perform a second decoding operation on the postfix subsequence to determine a second integer. The communication manager 1206 may perform a third decoding operation on the first integer and the second integer to determine a third integer, the third decoding operation being associated with an alphabet, a sequence length, and an energy threshold, and the third decoding operation including determining a shifted third integer based at least in part on the second integer and the third integer, and determining the third integer based at least in part on the shifted third integer, a prefix subsequence energy, a prefix subsequence length, the sequence length, and the energy threshold. The communication manager 1206 may recover the plurality of information bits associated with a set of integers, the set of integers including the first integer, the second integer, and the third integer.

The communication manager 1206 may determine the prefix subsequence energy based at least in part on a set of energies associated with the prefix subsequence.

The number and arrangement of components shown in FIG. 12 are provided as an example. In practice, there may be additional components, fewer components, different components, or differently arranged components than those shown in FIG. 12. Furthermore, two or more components shown in FIG. 12 may be implemented within a single component, or a single component shown in FIG. 12 may be implemented as multiple, distributed components. Additionally, or alternatively, a set of (one or more) components shown in FIG. 12 may perform one or more functions described as being performed by another set of components shown in FIG. 12.

The following provides an overview of some Aspects of the present disclosure:

Aspect 1: A method of wireless communication performed by a transmitter device, comprising: receiving a plurality of information bits, the plurality of information bits being associated with a set of integers; performing a first encoding operation on a first integer, of the set of integers, the first encoding operation being associated with an alphabet, a sequence length, and an energy threshold, and including: determining a prefix subsequence energy based at least in part on a prefix subsequence length, the sequence length, the energy threshold, and the first integer, generating a shifted first integer based at least in part on the prefix subsequence energy and the first integer, and determining a second integer and a third integer based at least in part on the shifted first integer and the prefix subsequence energy; performing a second encoding operation on the second integer to generate a prefix subsequence; performing a third encoding operation on the third integer to generate a postfix subsequence; generating a symbol sequence based at least in part on the prefix subsequence and the postfix subsequence; and transmitting the symbol sequence to convey the plurality of information bits.

Aspect 2: The method of Aspect 1, wherein determining the second integer and the third integer comprises: determining the second integer based at least in part on the shifted first integer, the prefix subsequence length, and the prefix subsequence energy; and determining the third integer based at least in part on the second integer, the prefix subsequence length, the prefix subsequence energy, the sequence length, and the energy threshold.

Aspect 3: The method of any of Aspects 1-2, further comprising: determining a maximum postfix subsequence energy based at least in part on the prefix subsequence energy and the energy threshold.

Aspect 4: The method of Aspect 3, wherein the maximum postfix subsequence energy is equal to a difference between the energy threshold and the prefix subsequence energy.

Aspect 5: The method of any of Aspects 1-4, wherein the prefix subsequence has a length equal to the prefix subsequence length and has an energy equal to the prefix subsequence energy.

Aspect 6: The method of Aspect 3, wherein the postfix subsequence has a length equal to a difference between the sequence length and the prefix subsequence length and has an energy less than or equal to the maximum postfix subsequence energy.

Aspect 7: The method of any of Aspects 1-6, wherein performing the first encoding operation comprises: identifying a range of non-negative integers, wherein each integer, of the range of nonnegative integers, comprises a candidate energy associated with the prefix subsequence energy; determining a plurality of sequence quantities, wherein: each sequence quantity, of the plurality of sequence quantities, corresponds to a respective integer of the range of non-negative integers; a sequence quantity, of the plurality of sequence quantities, corresponds to a cardinality of a first set of subsequences over the alphabet, each subsequence, of the first set of subsequences, having a length equal to the prefix subsequence length, and having an energy equal to an integer of the range of non-negative integers; determining a plurality of cumulative sequence quantities, wherein: each cumulative sequence quantity, of the plurality of cumulative sequence quantities, corresponds to a respective integer of the range of nonnegative integers; a cumulative sequence quantity, of the plurality of cumulative sequence quantities, corresponds to a cardinality of a second set of subsequences over the alphabet, each subsequence, of the second set of subsequences, having a length equal to a difference between the sequence length and the prefix subsequence length, and having an energy at most equal to a difference between a maximum sequence energy and the integer of the range of nonnegative integers; partitioning a first interval into a plurality of subintervals based at least in part on the plurality of sequence quantities and the plurality of cumulative sequence quantities, each subinterval, of the plurality of subintervals, corresponding to a respective sequence quantity of the plurality of sequence quantities and a respective cumulative sequence quantity of the plurality of cumulative sequence quantities; and determining a subinterval, of the plurality of subintervals, based at least in part on identifying that the first integer is a member of the subinterval; and determining the prefix subsequence energy based at least in part on identifying the integer, of the range of non-negative integers, that corresponds to the subinterval.

Aspect 8: The method of Aspect 7, wherein determining the plurality of sequence quantities comprises: approximating a logarithm of each sequence quantity of the plurality of sequence quantities; and exponentiating the logarithm of each sequence quantity of the plurality of sequence quantities.

Aspect 9: The method of Aspect 7, wherein determining the plurality of cumulative sequence quantities comprises: approximating a logarithm of each cumulative sequence quantity of the plurality of cumulative sequence quantities; and exponentiating the logarithm of each cumulative sequence quantity of the plurality of cumulative sequence quantities.

Aspect 10: The method of Aspect 7, wherein generating the shifted first integer is based at least in part on the first integer, the plurality of sequence quantities, and the plurality of cumulative sequence quantities.

Aspect 11: The method of Aspect 7, wherein the second integer is less than the sequence quantity, of the plurality of sequence quantities, and wherein the third integer is less than the cumulative sequence quantity, of the plurality of cumulative sequence quantities.

Aspect 12: The method of any of Aspects 1-11, wherein the second encoding operation is performed in parallel with performing the third encoding operation.

Aspect 13: The method of any of Aspects 1-12, wherein the symbol sequence has a length equal to the sequence length and has an energy at most equal to the energy threshold, and wherein each element of the symbol sequence is included in the alphabet.

Aspect 14: The method of any of Aspects 1-13, wherein the sequence length is a power of 2, and further wherein the prefix subsequence length is a power of 2.

Aspect 15: The method of any of Aspects 1-14, wherein the plurality of information bits corresponds to a binary expansion of the first integer.

Aspect 16: The method of any of Aspects 1-15, wherein the energy threshold is based at least in part on the sequence length and a normalized energy threshold.

Aspect 17: The method of any of Aspects 1-16, wherein performing the second encoding operation comprises: determining a plurality of sub-subsequence energies based at least in part on the second integer, the prefix subsequence length, and the prefix subsequence energy; determining a plurality of integers based at least in part on the second plurality of sub-subsequence energies and the second integer, wherein each integer, of the second plurality of integers, corresponds to a respective sub-subsequence energy, of the second plurality of sub-subsequence energies; encoding each integer, of the plurality of integers, into a respective sub-subsequence, of a plurality of sub-subsequences, wherein each sub-subsequence, of the plurality of sub-subsequences, has an energy equal to a respective sub-subsequence energy, of the of sub-subsequence energies; and concatenating the plurality of sub-subsequences, wherein the prefix subsequence is based at least in part on the concatenating.

Aspect 18: The method of any of Aspects 1-17, wherein performing the third encoding operation comprises: determining a plurality of sub-subsequence energies based at least in part on the third integer and the maximum postfix subsequence energy; determining a plurality of integers based at least in part on the plurality of sub-subsequence energies and the third integer, wherein each integer, of the plurality of integers, corresponds to a respective sub-subsequence energy, of the third plurality of sub-subsequence energies; encoding each integer, of the plurality of integers, into a respective sub-subsequence, of a plurality of sub-subsequences, wherein each sub-subsequence, of the plurality of sub-subsequences, has an energy less than or equal to a respective sub-subsequence energy, of the plurality of sub-subsequence energies; and concatenating the plurality of sub-subsequences, wherein the postfix subsequence is based at least in part on the concatenating.

Aspect 19: A method of wireless communication performed by a receiver device, comprising: receiving a symbol sequence that conveys a plurality of information bits; determining a prefix subsequence and a postfix subsequence based at least in part on the symbol sequence; performing a first decoding operation on the prefix subsequence to determine a first integer; performing a second decoding operation on the postfix subsequence to determine a second integer; performing a third decoding operation on the first integer and the second integer to determine a third integer, the third decoding operation being associated with an alphabet, a sequence length, and an energy threshold, and including: determining a shifted third integer based at least in part on the second integer and the third integer, and determining the third integer based at least in part on the shifted third integer, a prefix subsequence energy, a prefix subsequence length, the sequence length, and the energy threshold; and recovering the plurality of information bits associated with a set of integers, the set of integers including the first integer, the second integer, and the third integer.

Aspect 20: The method of Aspect 19, wherein the prefix subsequence has a length equal to the prefix subsequence length and has an energy equal to the prefix subsequence energy.

Aspect 21: The method of any of Aspects 19-20, wherein the first decoding operation is performed in parallel with performing the second decoding operation.

Aspect 22: The method of any of Aspects 19-21, wherein the symbol sequence has a length equal to the sequence length and has an energy less than or equal to the energy threshold, and wherein each element of the symbol sequence is included in the alphabet.

Aspect 23: The method of any of Aspects 19-22, wherein the sequence length is a power of 2, and further wherein the prefix subsequence length is a power of 2.

Aspect 24: The method of any of Aspects 19-23, wherein determining the shifted third integer comprises: determining the shifted third integer based at least in part on the prefix subsequence length, the prefix subsequence energy, the sequence length, and the energy threshold.

Aspect 25: The method of any of Aspects 19-24, further comprising: determining the prefix subsequence energy based at least in part on a set of energies associated with the prefix subsequence.

Aspect 26: An apparatus for wireless communication at a device, comprising a processor; memory coupled with the processor; and instructions stored in the memory and executable by the processor to cause the apparatus to perform the method of one or more of Aspects 1-25.

Aspect 25: A device for wireless communication, comprising a memory and one or more processors coupled to the memory, the one or more processors configured to perform the method of one or more of Aspects 1-25.

Aspect 26: An apparatus for wireless communication, comprising at least one means for performing the method of one or more of Aspects 1-25.

Aspect 27: A non-transitory computer-readable medium storing code for wireless communication, the code comprising instructions executable by a processor to perform the method of one or more of Aspects 1-25.

Aspect 28: A non-transitory computer-readable medium storing a set of instructions for wireless communication, the set of instructions comprising one or more instructions that, when executed by one or more processors of a device, cause the device to perform the method of one or more of Aspects 1-25.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

1. A transmitter device for wireless communication, comprising:
a memory; and
one or more processors, coupled to the memory, configured to:
receive a plurality of information bits, the plurality of information bits being associated with a set of integers;
perform a first encoding operation on a first integer, of the set of integers, the first encoding operation being associated with an alphabet, a sequence length, and an energy threshold and, to perform the first encoding operation, the one or more processors being configured to:
determine a prefix subsequence energy based at least in part on a prefix subsequence length, the sequence length, the energy threshold, and the first integer,
generate a shifted first integer based at least in part on the prefix subsequence energy and the first integer, and
determine a second integer and a third integer based at least in part on the shifted first integer and the prefix subsequence energy;
perform a second encoding operation on the second integer to generate a prefix subsequence;
perform a third encoding operation on the third integer to generate a postfix subsequence;
generate a symbol sequence based at least in part on the prefix subsequence and the postfix subsequence; and
transmit the symbol sequence to convey the plurality of information bits.

2. The transmitter device of claim 1, wherein the one or more processors, to determine the second integer and the third integer, are configured to:
determine the second integer based at least in part on the shifted first integer, the prefix subsequence length, and the prefix subsequence energy; and
determine the third integer based at least in part on the second integer, the prefix subsequence length, the prefix subsequence energy, the sequence length, and the energy threshold.

3. The transmitter device of claim 1, wherein the one or more processors are further configured to:
determine a maximum postfix subsequence energy based at least in part on the prefix subsequence energy and the energy threshold.

4. The transmitter device of claim 3, wherein the maximum postfix subsequence energy is equal to a difference between the energy threshold and the prefix subsequence energy.

5. The transmitter device of claim 1, wherein the prefix subsequence has a length equal to the prefix subsequence length and has an energy equal to the prefix subsequence energy.

6. The transmitter device of claim 3, wherein the postfix subsequence has a length equal to a difference between the sequence length and the prefix subsequence length and has an energy less than or equal to the maximum postfix subsequence energy.

7. The transmitter device of claim 1, wherein the one or more processors, to perform the first encoding operation, are configured to:
identify a range of non-negative integers, wherein each integer, of the range of nonnegative integers, comprises a candidate energy associated with the prefix subsequence energy;
determine a plurality of sequence quantities, wherein:
each sequence quantity, of the plurality of sequence quantities, corresponds to a respective integer of the range of non-negative integers;
a sequence quantity, of the plurality of sequence quantities, corresponds to a cardinality of a first set of subsequences over the alphabet, each subsequence, of the first set of subsequences, having a length equal to the prefix subsequence length, and having an energy equal to an integer of the range of non-negative integers;
determine a plurality of cumulative sequence quantities, wherein:
each cumulative sequence quantity, of the plurality of cumulative sequence quantities, corresponds to a respective integer of the range of nonnegative integers;
a cumulative sequence quantity, of the plurality of cumulative sequence quantities, corresponds to a cardinality of a second set of subsequences over the alphabet, each subsequence, of the second set of subsequences, having a length equal to a difference between the sequence length and the prefix subsequence length, and having an energy at most equal to a difference between a maximum sequence energy and the integer of the range of nonnegative integers;
partition a first interval into a plurality of subintervals based at least in part on the plurality of sequence quantities and the plurality of cumulative sequence quantities, each subinterval, of the plurality of subintervals, corresponding to a respective sequence quantity of the plurality of sequence quantities and a respective cumulative sequence quantity of the plurality of cumulative sequence quantities; and
determine a subinterval, of the plurality of subintervals, based at least in part on identifying that the first integer is a member of the subinterval; and
determine the prefix subsequence energy based at least in part on identifying the integer, of the range of non-negative integers, that corresponds to the subinterval.

8. The transmitter device of claim 7, wherein the one or more processors, to determine the plurality of sequence quantities, are configured to:
approximate a logarithm of each sequence quantity of the plurality of sequence quantities; and
exponentiate the logarithm of each sequence quantity of the plurality of sequence quantities.

9. The transmitter device of claim 7, wherein the one or more processors, to determine the plurality of cumulative sequence quantities, are configured to:
approximate a logarithm of each cumulative sequence quantity of the plurality of cumulative sequence quantities; and
exponentiate the logarithm of each cumulative sequence quantity of the plurality of cumulative sequence quantities.

10. The transmitter device of claim 7, wherein generating the shifted first integer is based at least in part on the first integer, the plurality of sequence quantities, and the plurality of cumulative sequence quantities.

11-18. (canceled)

19. A receiver device for wireless communication, comprising:
a memory; and
one or more processors, coupled to the memory, configured to:
receive a symbol sequence that conveys a plurality of information bits;
determine a prefix subsequence and a postfix subsequence based at least in part on the symbol sequence;
perform a first decoding operation on the prefix subsequence to determine a first integer;
perform a second decoding operation on the postfix subsequence to determine a second integer;
perform a third decoding operation on the first integer and the second integer to determine a third integer, the third decoding operation being associated with an alphabet, a sequence length, and an energy threshold, and to perform the third decoding operation, the one or more processors being configured to:
determine a shifted third integer based at least in part on the second integer and the third integer, and
determine the third integer based at least in part on the shifted third integer, a prefix subsequence energy, a prefix subsequence length, the sequence length, and the energy threshold; and
recover the plurality of information bits associated with a set of integers, the set of integers including the first integer, the second integer, and the third integer.

20. The receiver device of claim 19, wherein the prefix subsequence has a length equal to the prefix subsequence length and has an energy equal to the prefix subsequence energy.

21. The receiver device of claim 19, wherein the first decoding operation is performed in parallel with performing the second decoding operation.

22. The receiver device of claim 19, wherein the symbol sequence has a length equal to the sequence length and has an energy less than or equal to the energy threshold, and wherein each element of the symbol sequence is included in the alphabet.

23. The receiver device of claim 19, wherein the sequence length is a power of 2, and further wherein the prefix subsequence length is a power of 2.

24. The receiver device of claim 19, wherein the one or more processors, to determine the shifted third integer, are configured to:
determine the shifted third integer based at least in part on the prefix subsequence length, the prefix subsequence energy, the sequence length, and the energy threshold.

25. The receiver device of claim 19, wherein the one or more processors are further configured to:
determine the prefix subsequence energy based at least in part on a set of energies associated with the prefix subsequence.

26. A method of wireless communication performed by a transmitter device, comprising:
receiving a plurality of information bits, the plurality of information bits being associated with a set of integers;
performing a first encoding operation on a first integer, of the set of integers, the first encoding operation being associated with an alphabet, a sequence length, and an energy threshold, and including:
determining a prefix subsequence energy based at least in part on a prefix subsequence length, the sequence length, the energy threshold, and the first integer,
generating a shifted first integer based at least in part on the prefix subsequence energy and the first integer, and
determining a second integer and a third integer based at least in part on the shifted first integer and the prefix subsequence energy;
performing a second encoding operation on the second integer to generate a prefix subsequence;
performing a third encoding operation on the third integer to generate a postfix subsequence;
generating a symbol sequence based at least in part on the prefix subsequence and the postfix subsequence; and
transmitting the symbol sequence to convey the plurality of information bits.

27. The method of claim 26, wherein determining the second integer and the third integer comprises:
determining the second integer based at least in part on the shifted first integer, the prefix subsequence length, and the prefix subsequence energy; and
determining the third integer based at least in part on the second integer, the prefix subsequence length, the prefix subsequence energy, the sequence length, and the energy threshold.

28. The method of claim 26, further comprising:
determining a maximum postfix subsequence energy based at least in part on the prefix subsequence energy and the energy threshold.

29-30. (canceled)
